(19) United States
(12) Patent Application Publication
(10) Pub. No.: US 2025/0232729 A1
(43) Pub. Date: Jul. 17, 2025

(54) DISPLAY APPARATUS AND DISPLAY PANEL

(71) Applicant: LG Display Co., Ltd., Seoul (KR)

(72) Inventor: In Seop KIM, Paju-si (KR)

(21) Appl. No.: 18/738,872

(22) Filed: Jun. 10, 2024

(30) Foreign Application Priority Data
Jan. 16, 2024 (KR) 10-2024-0006725

(51) Int. Cl. G09G 3/3266; B60K 35/22

(52) U.S. Cl. CPC G09G 3/3266; B60K 35/22; G09G 2330/06

(57) ABSTRACT

A display apparatus comprising a display panel including a plurality of subpixels in a display area, a gate driving circuit disposed along a first direction in a first area of the display panel, a gate clock line disposed along the first direction in the first area, and a second gate clock line disposed along the first direction in the first area, and disposed along a second direction in a second area of the display panel.

### CROSS-REFERENCE TO RELATED APPLICATION

This application claims priority to Korean Patent Application No. 10-2024-0006725, filed on Jan. 16, 2024, the entire contents of which is hereby expressly incorporated by reference into the present application.

### BACKGROUND

### Technical Field

The present disclosure relate to a display apparatus and a display panel, and more specifically, a display apparatus and a display panel capable of effectively reducing an electromagnetic noise.

### Description of the Related Art

Representative display apparatuses for displaying an image based on digital data include liquid crystal display (LCD) apparatuses using liquid crystal and organic light emitting display apparatuses using organic light emitting diodes OLEDs.

Among these display apparatuses, organic light emitting display apparatuses use light emitting diodes that emit light on their own, so they have advantages in terms of fast response speed, contrast ratio, luminous efficiency, luminance, and viewing angle. In this case, the light emitting diode can be implemented as an inorganic or organic material.

The organic light emitting display apparatus may include light emitting diodes disposed in each of a plurality of subpixels arranged on a display panel, and may control the luminance expressed by subpixels and display images by controlling the voltage flowing through the light emitting diodes and thereby emitting light in each light emitting diode.

### SUMMARY

The display apparatus may include signal lines transmitting various signals, and electromagnetic noise may be generated inside and outside the display apparatus by signals supplied to the signal lines.

When the electromagnetic noise is generated in the display apparatus, image quality may be degraded by malfunction of the display apparatus due to the electromagnetic noise.

The inventor of the present disclosure has invented a display apparatus and a display panel capable of, among others, effectively reducing an electromagnetic noise.

Aspects of the present disclosure may provide a display apparatus and a display panel capable of effectively reducing defect due to an electromagnetic noise.

According to aspects of the present disclosure, a display apparatus may comprise a display panel including a plurality of subpixels in a display area, a gate driving circuit disposed along a first direction in a first area of the display panel, a gate clock line disposed along the first direction in the first area, and a second gate clock line disposed along the first direction in the first area, and disposed along a second direction the second area of the display panel.

According to aspects of the present disclosure, a display panel may comprise a display area including a plurality of subpixels, a gate driving circuit disposed along a first direction in a first area of a non-display area outside of the display area, a first gate clock line disposed along the first direction in the first area, and a second gate clock line disposed along the first direction in the first area, and disposed along a second direction in a second area of the non-display area.

According to aspects of the present disclosure, it is possible to reduce defect due to an electromagnetic noise using a clock line.

According to aspects of the present disclosure, it is possible to effectively reduce defect due to an electromagnetic noise and to operate at a low power by an arrangement of an emission clock line and a scan clock line.

According to aspects of the present disclosure, it is possible to effectively reduce defect due to an electromagnetic noise by forming an emission clock line and the scan clock line in a closed loop structure.

According to aspects of the present disclosure, it is possible to effectively reduce defect due to an electromagnetic noise by controlling widths of an emission clock line and the scan clock line in a non-display area.

### DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

FIG. 1 illustrates a vehicle system including a display apparatus according to aspects of the present disclosure.

FIG. 2 illustrates a configuration of a display apparatus according to aspects of the present disclosure.

FIG. 3 illustrates a subpixel circuit according to aspects of the present disclosure.

FIG. 4 illustrates a gate driving circuit according to aspects of the present disclosure.

FIG. 5 is a block diagram illustrating a gate driving integrated circuit according to aspects of the present disclosure;

FIG. 6 is a signal waveform illustrating a Q node voltage of a shift register according to a gate clock according to aspects of the present disclosure.

FIG. 7 illustrates a clock line according to aspects of the present disclosure;

FIG. 8 illustrates a structure of a clock line according to aspects of the present disclosure.

FIG. 9 illustrates waveforms of a gate clock and a second gate clock according to aspects of the present disclosure.

FIG. 10 illustrates a circuit configured to generate a second gate clock according to aspects of the present disclosure.

FIGS. 11A and 11B illustrate measuring noise according to aspects of the present disclosure.

FIG. 12 illustrates an arrangement of clock lines according to aspects of the present disclosure.

FIG. 13 illustrates a touch electrode structure in a display apparatus according to aspects of the present disclosure.

FIG. 14 is a cross-sectional view exemplarily illustrating a display apparatus according to aspects of the present disclosure.

FIG. 15 is a cross-sectional diagram of a unit subpixel according to aspects of the present disclosure.

FIG. 16 illustrates a light emitting element according to aspects of the present disclosure.

FIG. 17 illustrates a light-emitting element according to another aspects of the present disclosure.

### DETAILED DESCRIPTION

Reference is now made in detail to aspects of the present disclosure, examples of which may be illustrated in the accompanying drawings. In the following description, when a detailed description of well-known functions, the structures, or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

Shapes (e.g., sizes, lengths, widths, heights, thicknesses, locations, radii, diameters, and areas), dimensions, ratios, angles, numbers, and the like disclosed herein, including those illustrated in the drawings, are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where a term like “comprise,” “have,” “include,” “contain,” “constitute,” “make up of,” “formed of,” or the like is used with respect to one or more other elements, one or more other elements may be added unless a term, such as “only” or the like is used. The terms used in the present disclosure are merely used in order to describe example aspects, and are not intended to limit the scope of the present disclosure. The terms of a singular form may include plural forms unless the context clearly indicates otherwise.

The word “exemplary” is used to mean serving as an example or illustration, unless otherwise specified. Aspects are example aspects. “Aspects,” “examples,” and the like should not be construed as preferred or advantageous over other implementations. An aspect, an example, an example aspect, or the like may refer to one or more aspects, one or more examples, one or more example aspects, or the like, unless stated otherwise. Further, the term “may” encompasses all the meanings of the term “can.”

In one or more aspects, unless explicitly stated otherwise, element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A”, “B”, “(a)”, or “(b)”, or the like may be used. These terms are intended to identify the corresponding element(s) from the other element(s), and these are not used to define the essence, basis, order, sequence, or number of elements.

For the expression that an element (e.g., layer, film, region, component, section, or the like) is described as “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item”, may represent (i) a combination of items provided by two or more of the first item, the second item, and the third item and (ii) only one of the first item, the second item, and the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); some combinations of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, and may be operated, linked, or driven together in various ways. Aspects of the present disclosure may be implemented or carried out independently from each other, or may be implemented or carried out together in a co-dependent or related relationship. In one or more aspects, the components of each apparatus according to various aspects of the present disclosure may be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example aspects.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

“X-axis direction”, “Y-axis direction” and “Z-axis direction” should not be construed by a geometric relation only of a mutual vertical relation and may have broader directionality within the range that elements of the present disclosure may act functionally.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

Hereinafter, various aspects of the present disclosure will be described in detail with reference to the accompanying drawings.

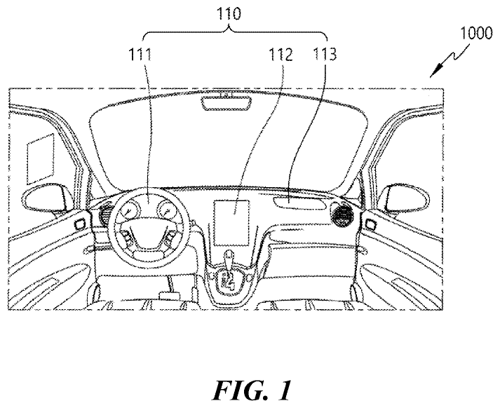

FIG. 1 illustrates a vehicle system including a display apparatus according to aspects of the present disclosure.

Referring to FIG. 1, an inside of the vehicle system 1000 according to aspects of the present disclosure may include a driver's seat, a passenger's seat, a dashboard, which has various instruments for driving, disposed in front of the driver's seat and passenger's seat, and a center fascia with a control plate for electronic apparatuses

The dashboard may include a first display panel 111 configured to display information for driving, including a speedometer. The first display panel 111 may be referred to as an dashboard display panel.

The first display panel 111 is a display panel for allowing the vehicle system 1000 to be driven safely by transmitting information for the driving status of the vehicle system 1000 and the operation of various electronic apparatuses installed in the vehicle system 1000 to the driver. The first display panel 111 disposed behind the steering wheel relative to the driver's seat may include a speedometer for indicating a driving speed, a tripmeter for indicating a driving distance, a tachometer for indicating engine rotation speed, a fuel gauge, a water temperature gauge, an engine temperature gauge, and various warning lamps.

The center fascia may be disposed between the driver's seat and the passenger's seat, and may correspond to the area where the dashboard and shift lever meet vertically. An audio, an air conditioner, a heater controller, a navigator, an air vent, a cigar jack, an ashtray, a cup holder, etc., may be disposed on the center fascia. Additionally, the center fascia may include a second display panel 112.

The second display panel 112 may display a route to the destination or display a map image corresponding to the current location, and may display a user interface related to the control of various electronic apparatuses in the vehicle system 1000. Additionally, when the vehicle system 1000 is connected to a mobile apparatus, a screen provided by the mobile apparatus may be displayed in the second display panel 112.

The second display panel 112 disposed between the driver's seat and the passenger's seat of the vehicle system 1000 may be referred to as a center fascia display panel.

Furthermore, a third display panel 113 may be disposed on the front of the passenger's seat for the convenience of passengers. The third display panel 113 disposed on the passenger's seat may be referred to as the passenger's display panel.

Moreover, the display panel 110 may include at least one of a front window display panel, a side mirror display panel, a rear mirror display panel and a side window display panel in addition to the dashboard display panel 111, a center fascia display panel 112, and the passenger's display panel 113. Also, various types of display panels may be more installed.

The front window display panel may be a display panel that projects a virtual image on a partial area of the front window that can see through the front of the vehicle system 1000. By displaying a vehicle speed, a remaining fuel, and route information through the front window display panel, it may reduce the driver's unnecessary shifting of gaze elsewhere.

The side mirror display panel may be a display panel that can display a side image captured through a side camera on a partial or entire area of a side mirror to view the side of the vehicle system 1000. Therefore, the driver may check not only the side image reflected through the side mirror, but also the side image captured through the side camera through the side mirror display panel.

The rear mirror display panel may be a display panel that can display a rear image captured through a rear camera on a partial or entire area of a rear mirror to view the rear of the vehicle system 1000. Therefore, the driver may check not only the rear image reflected through the rear mirror, but also the rear image captured through the rear camera through the rear mirror display panel.

The side window display panel may be a display panel for projecting a virtual image on a partial area of the side window that can see through the side of the vehicle system 1000. Various information for the vehicle system 1000 may be displayed through the side window display panel.

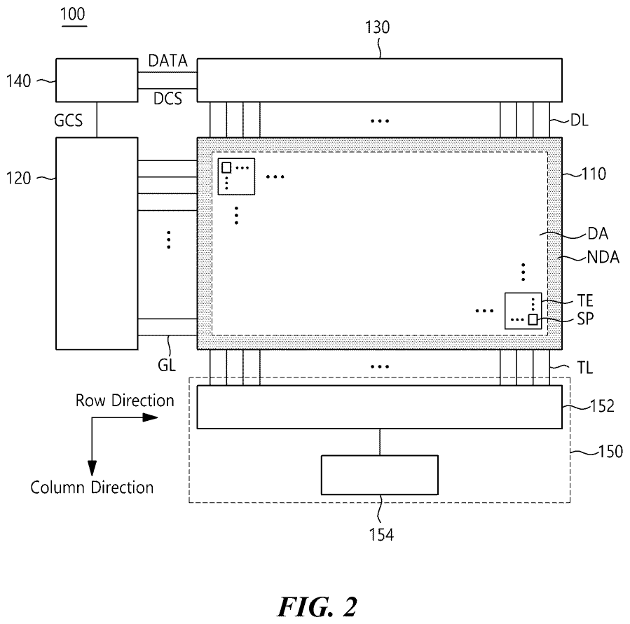

FIG. 2 illustrates a configuration of a display apparatus according to aspects of the present disclosure.

Referring to FIG. 2, a display apparatus 100 according to aspects of the present disclosure may include a display panel 110, a data driving circuit 130, a gate driving circuit 120, and a timing controller 140 as components configured to display images.

The display panel 110 may include a dashboard display panel 111, a center fascia display panel 112, and a passenger display panel 113, but aspects of the present disclosure are not limited thereto.

The display panel 110 may include a display area DA in which images are displayed and a non-display area NDA in which no image is displayed.

The non-display area NDA may be an outer area of the display area DA and be referred to as a bezel area. The non-display area NDA may be an area visible from the front of the display apparatus 100 or an area that is bent and not visible from the front of the display apparatus 100.

The display panel 110 may include a plurality of subpixels SP. For example, the display apparatus 100 may be various types of display apparatuses including a liquid crystal display apparatus, an organic light emitting display apparatus, a micro light emitting diode (micro LED) display apparatus, and a quantum dot display apparatus, but aspects of the present disclosure are not limited thereto.

The structure of each of the plurality of subpixels SP may vary according to the type of the display apparatus 100. For example, when the display apparatus 100 is a self-emission display apparatus in which the subpixels SP emit light by themselves, each subpixel SP may include a light emitting element that emits light by itself, one or more transistors, and one or more capacitors.

The display panel 110 may further include various types of signal lines to drive the plurality of subpixels SP. For example, various types of signal lines may include a plurality of data lines DL transferring data signals (also referred to as data voltages or image data) and a plurality of gate lines GL transferring gate signals (also referred to as scan signals or emission signals).

The plurality of data lines DL and the plurality of gate lines GL may cross each other. Each of the plurality of data lines DL may be disposed to be extending in a column direction. Each of the plurality of gate lines GL may be disposed to be extending in a row direction.

Here, the column direction and the row direction are relative. For example, the column direction may be a vertical direction and the row direction may be a horizontal direction. As another example, the column direction may be a horizontal direction and the row direction may be a vertical direction.

The data driving circuit 130 may be a circuit configured to drive the plurality of data lines DL. The data driving circuit 130 may supply data signals to the plurality of data lines DL. The gate driving circuit 120 may be a circuit configured to drive the plurality of gate lines GL. The gate driving circuit 120 may supply gate signals to the plurality of gate lines GL.

The timing controller 140 may control the data driving circuit 130 and the gate driving circuit 120. The timing controller 140 may control driving timings for the plurality of data lines DL and driving timings for the plurality of gate lines GL.

The timing controller 140 may supply various types of data driving control signals DCS to the data driving circuit 130 to control the data driving circuit 130 and may supply various types of gate driving control signals GCS to the gate driving circuit 230 to control the gate driving circuit 120.

The data driving circuit 130 may supply data voltages to the plurality of data lines DL according to the driving timing control by the timing controller 140. The data driving circuit 130 may receive digital image data DATA from the timing controller 140 and may convert the received image data DATA into analog data voltages and output them to the plurality of data lines DL.

The gate driving circuit 120 may supply gate signals to the plurality of gate lines GL according to the timing control of the timing controller 140. The gate driving circuit 120 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL. The turn-on level voltage may be a high level voltage, and the turn-off level voltage may be a low level voltage. In another example, the turn-on level voltage may be a low level voltage, and the turn-off level voltage may be a high level voltage.

The gate driving circuit 120 may include one or more gate driving integrated circuits (GDIC). The gate driving circuit 120 may be located on only one side or both sides of the display panel 110 depending on the driving method. Alternatively, the gate driving circuit 120 may be a Gate In Panel (GIP) formed directly in the non-display area NDA of the display panel 110.

To provide a touch sensing function as well as an image display function, the display apparatus 100 may include a touch screen panel and a touch circuit 150 that senses the touch screen panel to detect whether a touch occurs by a touch object, such as a finger or pen, or the position of the touch.

The touch circuit 150 may include a touch driving circuit 152 that drives and senses the touch screen panel and generates and outputs touch sensing data and a touch controller 154 that may detect an occurrence of a touch or the position of the touch using touch sensing data.

The touch screen panel may include a plurality of touch electrodes TE as touch sensors. The touch screen panel may further include a plurality of touch lines TL for electrically connecting the plurality of touch electrodes TE and the touch driving circuit 152. The touch screen panel or touch electrode TE is also referred to as a touch sensor.

The touch screen panel may exist outside or inside the display panel 110. When the touch screen panel exists outside the display panel 110, the touch screen panel is referred to as an external-type touch screen panel. When the touch screen panel is the external-type, the touch screen panel and the display panel 110 may be separately manufactured or may be combined. The external-type touch screen panel may include a substrate and a plurality of touch electrodes TE on the substrate.

When the touch screen panel exists inside the display panel 110, the touch screen panel is referred to as an internal-type touch screen panel. In the internal-type touch screen panel, the touch screen panel may be formed in the display panel 110 during a manufacturing process of the display panel 110.

The touch driving circuit 152 may supply a touch driving signal to at least one of the plurality of touch electrodes TE and detect a touch sensing signal transferred from at least one touch electrode TE among the plurality of touch electrodes TE, generating touch sensing data.

The touch circuit 150 may perform touch sensing in a self-capacitance sensing scheme or a mutual-capacitance sensing scheme.

When the touch circuit 150 performs touch sensing in the self-capacitance sensing scheme, the touch circuit 150 may perform touch sensing based on capacitance between each touch electrode TE and the touch object (e.g., finger or pen).

When the touch circuit 150 performs touch sensing in the mutual-capacitance sensing scheme, the touch circuit 150 may perform touch sensing based on capacitance between the touch electrodes TE.

According to the mutual-capacitance sensing scheme, the plurality of touch electrodes TE may include driving touch electrodes and sensing touch electrodes. The touch driving circuit 152 may drive the driving touch electrode by the touch driving signal and may detect the touch sensing signal from the sensing touch electrode.

According to the self-capacitance sensing scheme, each of the touch electrodes TE may serve both as a driving touch electrode and as a sensing touch electrode. The touch driving circuit 152 may drive all or some of the plurality of touch electrodes TE and sense all or some of the plurality of touch electrodes TE.

The touch driving circuit 152 and the touch controller 154 may be implemented as separate devices or as a single device.

In another example, the touch driving circuit 152 and the data driving circuit 130 may be implemented as separate integrated circuits. Alternatively, the whole or part of the touch driving circuit 152 and the whole or part of the data driving circuit 130 may be integrated into a single integrated circuit.

The display apparatus 100 according to aspects of the present disclosure may be a self-emissive display apparatus having self-emissive light emitting elements disposed on the display panel 110, such as an organic light emitting display apparatus, a quantum dot display apparatus, a micro LED display apparatus, but aspects of the present disclosure are not limited thereto.

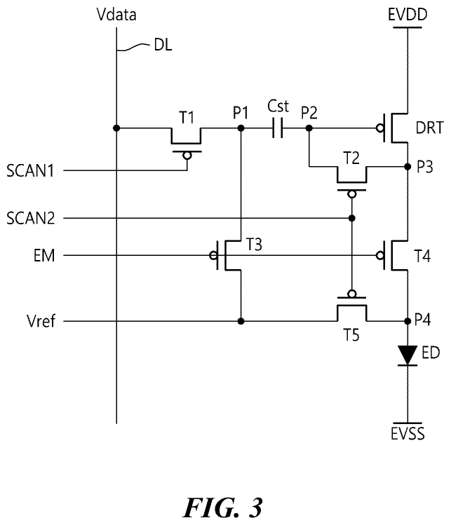

FIG. 3 illustrates a subpixel circuit according to aspects of the present disclosure.

Referring to FIG. 3, the subpixel circuit of the display apparatus 100 according to aspects of the present disclosure may include a light emitting element ED, a driving transistor DRT, a plurality of switching transistors T1-T5, and a storage capacitor Cst.

The driving transistor DRT and a plurality of switching transistors T1-T5, which are included in the subpixel circuit, may be implemented as a PMOS type low temperature polysilicon (LTPS) transistors, thereby securing a desired response time characteristic.

In another example, at least one switching transistor among the plurality of switch transistors T1-T5 may be implemented as an NMOS type or PMOS type oxide transistor with a good leakage current characteristic when turned off, and the remaining switching transistors may be implemented as the PMOS type LTPS transistors with a good response time characteristic.

The light emitting element ED may emit light with an amount of driving current controlled by a gate-source voltage Vgs of the driving transistor DRT. An anode electrode of the light emitting element ED may be connected to a fourth node P4, and a cathode electrode of the light emitting element ED may be connected to a low-potential pixel voltage EVSS.

When the light emitting element ED is an organic light emitting diode, an organic compound layer may be disposed between the anode electrode and the cathode electrode.

The organic compound layer may include a hole injection layer (HIL), a hole transport layer (HTL), an electron blocking layer (EBL), an emission layer (EML), an electron transport layer (ETL), a hole blocking layer (HBL), and an electron injection layer (EIL). For example, two or more organic compound layers emitting different colors may be stacked according to a tandem structure. For example, a charge generation layer may be included between two or more organic compound layers. The charge generation layer may include an N-type charge generation layer and a P-type charge generation layer.

When a driving current flows through the light emitting element ED, holes passing through the hole transport layer (HTL) and electrons passing through the electron transport layer (ETL) move to the emission layer (EML) to form excitons, and as a result, the emission layer (EML) may emit visible light.

The driving transistor DRT may control the driving current flowing through the light emitting element ED according to the gate-source voltage Vgs. In the driving transistor DRT, the gate electrode may be connected to a second node P2, the drain electrode (or the source electrode) may be connected to the driving voltage line supplying the high-potential pixel voltage EVDD, and the source electrode (or the drain electrode) may be connected to a third node P3.

The subpixel circuit may include a first switching transistor T1 to a fifth switching transistor T5 and a storage capacitor Cst capable of sampling the gate-source voltage Vgs to compensate for the threshold voltage or mobility of the driving transistor DRT.

The first switching transistor T1 may be connected between the data line DL and the first node P1. The first switching transistor T1 may be switched according to a first scan signal SCAN1. In the first switching transistor T1, the gate electrode may be connected to a first gate line to which the first scan signal SCAN1 is supplied, the drain electrode (or the source electrode) may be connected to the data line DL and the source electrode (or the drain electrode) may be connected to the first node P1.

A second switching transistor T2 may be connected between the second node P2 and the third node P3. The second switching transistor T2 may be switched according to a second scan signal SCAN2. In the second switching transistor T2, the gate electrode may be connected to a second gate line to which the second scan signal SCAN2 is supplied, the drain electrode (or the source electrode) may be connected to the third node P3 and the source electrode (or the drain electrode) may be connected to the second node P2.

Since a single electrode of the second switching transistor T2 is connected to the gate electrode of the driving transistor DRT, an off current characteristic should be good. Therefore, the second switching transistor T2 may be formed as a dual gate structure to suppress a leakage current when turned off.

In the dual gate structure, the first gate electrode and the second gate electrode are connected to each other so as to have the same potential, and a channel length becomes longer than that of a single gate structure. As the channel length increases, resistance increases and the leakage current decreases when turned off, thereby ensuring stability of operation. However, the second switching transistor T2 may be implemented with the single gate structure, and in this case, the second switching transistor T2 may be implemented as an oxide transistor.

A third switching transistor T3 may be connected between the node P1 and a reference voltage line to which a reference voltage Vref is supplied. The third switching transistor T3 may be switched according to an emission signal EM. In the third switching transistor T3, the gate electrode may be connected to a third gate line to which the emission signal EM is supplied, and the drain electrode (or the source electrode) may be connected to the first node P1 and the source electrode (or the drain electrode) may be connected to the reference voltage line.

A fourth switching transistor T4 may be connected between the third node P3 and the fourth node P4 which is an anode electrode of the light emitting element ED. The fourth switching transistor T4 may be switched according to the emission signal EM. In the fourth switching transistor T4, the gate electrode may be connected to the third gate line to which the emission signal EM is supplied, the drain electrode (or the source electrode) may be connected to the third node P3 and the source electrode (or the drain electrode) may be connected to the fourth node P4. The fourth switching transistor T4 controls the driving current flowing through the light emitting element ED, so it can be referred to as an emission control transistor.

A fifth switching transistor T5 may be connected between the fourth node P4 and the reference voltage line. The fifth switching transistor T5 may be switched according to the second scan signal SCAN2. In the fifth switching transistor T5, the gate electrode may be connected to the second gate line to which the second scan signal SCAN2 is supplied, the drain electrode (or the source electrode) may be connected to the fourth node P4 and the source electrode (or the drain electrode) may be connected to the reference voltage line.

The storage capacitor Cst may be connected between the first node P1 and the second node P2.

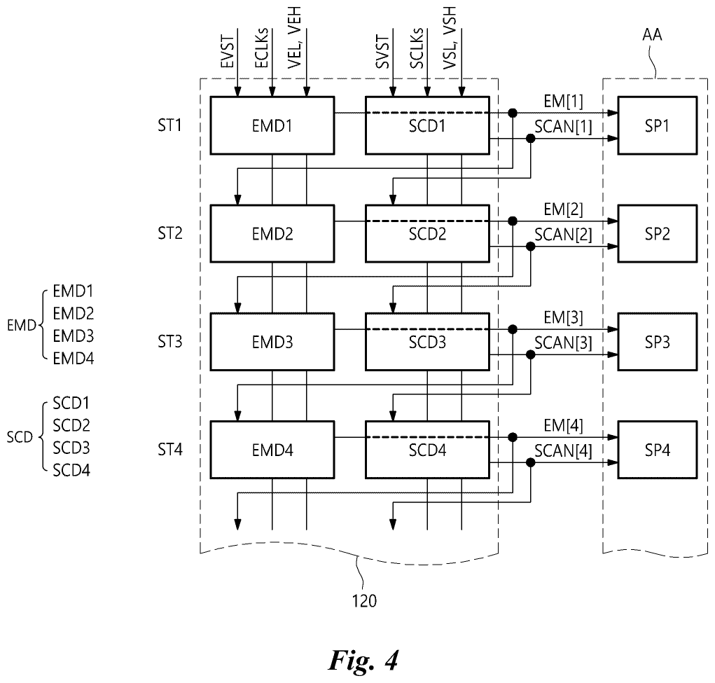

FIG. 4 is a block diagram illustrating a gate driving circuit according to aspects of the present disclosure.

Referring to FIG. 4, the gate driving circuit 120 of the display apparatus 100 according to aspects of the present disclosure may include a plurality of scan driving circuits SCD1-SCD4 and a plurality of emission driving circuits EMD1-EMD4.

The plurality of scan driving circuits SCD1-SCD4 may generate line scan signals

SCAN[1]-SCAN[4] used to control switching transistors included in a plurality of subpixels SP1-SP4. The plurality of emission driving circuits EMD1-EMD4 may generate emission signals used to control the emission control transistors included in the plurality of subpixels SP1-SP4.

Each of the line scan signals SCAN[1]-SCAN[4]) may include one or more scan signals configured to drive each subpixel SP1-SP4. For example, when the subpixel SP has the structure of FIG. 3, each of the first line scan signal SCAN[1] to the fourth line scan signal SCAN[4] may include a first scan signal SCAN1 and a second scan signal SCAN2.

In this case, the first scan driving circuit SCD1 may include a 1-1 scan driving circuit generating the first scan signal SCAN1 and a 1-2 scan driving circuit generating the second scan signal SCAN2. Additionally, the second scan driving circuit SCD2 may include a 2-1 scan driving circuit generating a first scan signal SCAN1 and a 2-2 scan driving circuit generating a second scan signal SCAN2.

It may be a gate driving integrated circuit, including a scan driving circuit and an emission driving circuit.

In addition, when the gate driving circuit 120 is implemented as a gate-in-panel (GIP) type, the scan driving circuit SCD and the emission driving circuit EMD may be GIP circuits, and may be arranged as multiple stages ST1, ST2, ST3, and ST4 in the bezel area of the display panel 110.

The emission driving circuit EMD may operate based on emission clocks ECLKs, an emission start signal EVST, a low-potential emission voltage VEL, and a high-potential emission voltage VEH to generate a line emission signals EM[1], EM[2], EM[3], and EM[4].

The first emission driving circuit EMD1 may generate the first line emission signal EM[1] using the emission start signal EVST. The second emission driving circuit EMD2 may generate a second line emission signal EM[2] using the first line emission signal EM[1] generated from the first emission driving circuit EMD1. In this way, other emission driving circuits from the second emission driving circuit EMD2 may use the line emission signal generated in the previous emission driving circuit as emission start signals.

The line emission signals EM[1], EM[2], EM[3], and EM[4] may be supplied to the display panel 110 through the corresponding subpixel lines, and each line emission signal EM[1], EM[2], EM[3], and EM[4] may include one or more emission signals based on the structure of the subpixel SP.

The scan driving circuit SCD may operate based on scan clocks SCLKs, a scan start signal SVST, a low-potential scan voltage VSL, and a high-potential scan voltage VSH to generate a line scan signals SCAN[1], SCAN[2], SCAN[3], and SCAN[4].

The first scan driving circuit SCD1 may generate the first line scan signal SCAN[1] using the scan start signal SVST. The second scan driving circuit SCD2 may generate a second line scan signal SCAN[2] using the first line scan signal SCAN[1] generated from the first scan driving circuit SCD1. In this way, other scan driving circuits from the second scan driving circuit SCD2 may use the line scan signal generated in the previous scan driving circuit as scan start signals.

The line scan signals SCAN[1], SCAN[2], SCAN[3], SCAN[4] may be supplied to the display panel 110 through the corresponding subpixel lines, and each line scan signal SCAN[1], SCAN[2], SCAN[3], SCAN[4] may include one or more scan signals depending on the structure of the subpixel SP.

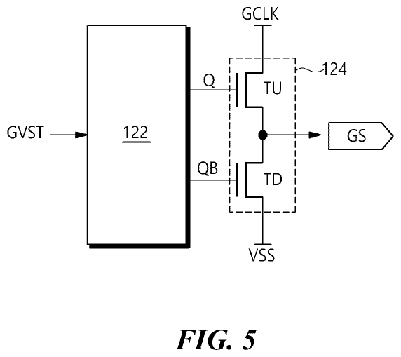

FIG. 5 is a block diagram illustrating a gate driving integrated circuit according to aspects of the present disclosure.

Referring to FIG. 5, the gate driving integrated circuit in the display apparatus 100 according to aspects of the present disclosure may include a shift register 122 and a buffer circuit 124. The gate driving integrated circuit may be a scan driving circuit or an emission driving circuit.

The gate driving integrated circuit starts to operate according to the gate start pulse GSP and outputs a gate signal GS according to the gate clock GCLK.

When the gate driving integrated circuit is a scan driving circuit SCD, the gate start signal GVST may be the scan start signal SVST, the gate clock GCLK may be the scan clock SCLK, and the gate signal GS may be a scan signal SCAN. For another example, when the gate driving integrated circuit is an emission driving circuit EMD, the gate start signal GVST may be the emission start signal EVST, the gate clock GCLK may be the emission clock ECLK, and the gate signal GS may be an emission signal EM.

The gate signal GS generated from the gate driving integrated circuit may be sequentially shifted and sequentially supplied through the gate line GL.

The buffer circuit 124 has two nodes Q and QB important to the gate driving state and may include a pull-up transistor TU and a pull-down transistor TD. The gate node of the pull-up transistor TU may correspond to the Q node, and the gate node of the pull-down transistor TD may correspond to the QB node.

The shift register 122 may also be referred to as a shift logic circuit and may be used to generate the gate signal GS in synchronization with the gate clock GCLK.

The shift register 122 may control the Q node and the QB node connected to the buffer circuit 124 so that the buffer circuit 124 may output the gate signal GS and, to this end, may include a plurality of transistors.

The shift register 122 may start to generate the gate signal GS, and the output of the shift register 122 may be sequentially turned on according to the gate clock GCLK. For example, it is possible to transfer the logic state of the shift register 122 to the buffer circuit 124 for sequentially determining on/off of the gate line GL by controlling the output time of the shift register 122 using the gate clock GCLK.

According to the shift register 122, the respective voltage states of the Q node and the QB node of the buffer circuit 124 may be different. Accordingly, the buffer circuit 124 may output a high-level gate voltage VGH for turning on the corresponding gate line GL to the corresponding gate line GL or a low-level gate voltage VGL for turning on the corresponding gate line GL to the corresponding gate line GL.

The low-level gate voltage VGL may correspond to the low-potential voltage VSS supplied to the drain electrode of the pull-down transistor TD.

The gate driving integrated circuit (or one of the gate driving integrated circuit) may further include a level shifter in addition to the shift register 122 and the buffer circuit 124.

The shift register 122 and the buffer circuit 124 constituting the gate driving integrated circuit may be connected in various structures.

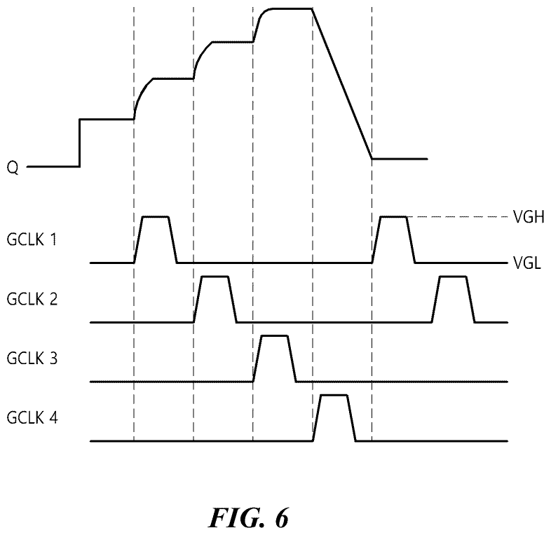

FIG. 6 is a signal waveform illustrating a Q node voltage of a shift register according to a gate clock according to aspects of the present disclosure.

Referring to FIGS. 5 and 6, in the gate driving integrated circuit of the display apparatus 100 according to aspects of the present disclosure, when a first gate clock GCLK1 is supplied to the buffer circuit 124 in a state that the Q node of the shift register 122 is charged by the high-level gate voltage VGH, the voltage of the floated Q node is bootstrapped and the high-level gate voltage VGH of the pull-up transistor TU is further increased.

In this case, the first gate signal supplied from the buffer circuit 124 to the first gate line may be maintained at the same level as the first gate clock GCLK1.

At this time, when the second gate clock GCLK2 is supplied to the adjacent buffer circuit 124, the voltage of the Q node further increases. As a result, the second scan signal supplied from the adjacent buffer circuit 124 to the second gate line may be increased to a level higher than the Q node voltage of the previous stage.

In a case of n-phase driving operation, which supplies gate signals sequentially for each nth gate line, the level of each gate signal supplied to the first gate line to nth gate lines may be different values due to voltage variation at the Q node.

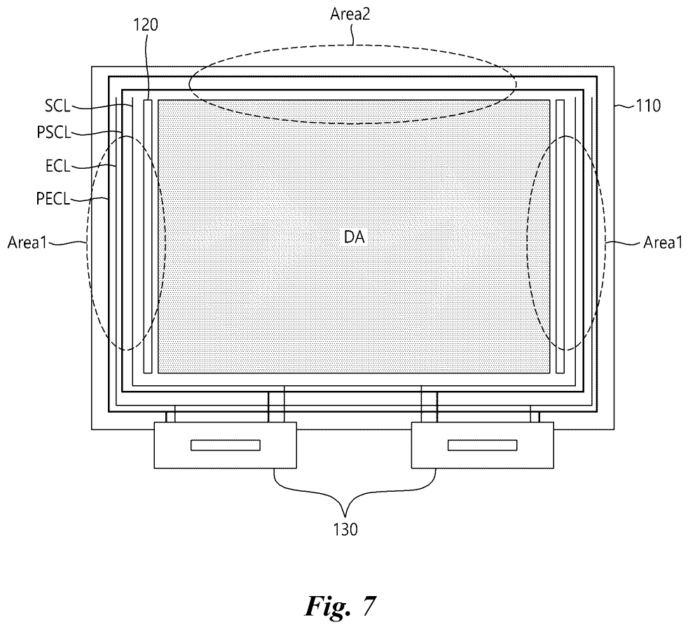

FIG. 7 illustrates a clock line according to aspects of the present disclosure.

Referring to FIG. 7, the gate driving circuit for supplying the gate signals to the display panel 110 in the non-display area NDA outside the display area DA in the display panel 110 may be formed in a GIP form in the display apparatus 100 according to aspects of the present disclosure.

A plurality of gate clock line for supplying the gate clock GCLK for generating and outputting the gate signals to the gate driving circuit 120 may be disposed in the non-display area NDA where subpixels are not formed in the display panel 110.

When the gate signals configured to drive the subpixel include an emission signal and a scan signal, the emission clock line ECL transmitting the emission clock and the scan clock line SCL transmitting the scan clock may correspond to the gate clock line.

The gate clock line may be arranged along the first direction in the first area Area1. The gate clock line may be arranged along the first direction in the first area Area1 to transmit the gate clock GCLK.

The gate clock line may include a scan clock line SCL and an emission clock line ECL. The scan clock line SCL and the emission clock line ECL may extend along the first direction in the first area Area1 where the gate driving circuit 120 is disposed. The first direction may be a vertical direction in which the gate driving circuit 120 is arranged.

The scan clock line SCL may be disposed close to the gate driving circuit 120, and the emission clock line ECL may be disposed along the first direction outside the scan clock line SCL. When the gate driving circuit 120 is disposed only at one side of the display panel 110, the scan clock line SCL and the emission clock line ECL may also be disposed on only one side of the display panel 110. For another example, when the gate driving circuit 120 is disposed at both sides of the display panel 110, the scan clock line SCL and the emission clock line ECL may also be disposed on both sides of the display panel 110.

Since the scan clock line SCL and the emission clock line ECL are signal lines configured to transmit the scan clock and the emission clock to the gate driving circuit 120, the scan clock line SCL and the emission clock line ECL may be disposed in the first area Area1 where the gate driving circuit 120 is disposed.

Referring to FIG. 6 and FIG. 7, capacitance may occur between adjacent gate lines during the transition of gate clocks GCLK1-GCLKn transmitted through gate clock lines, and noise may be generated due to electromagnetic interference between the gate lines.

Thus, the second scan clock line PSCL may be disposed in the non-display area NDA. Accordingly, electromagnetic noise caused by the gate clock GCLK may be reduced by applying the second clock. The second scan clock line PSCL may be a second gate clock line or a pseudo scan clock line, but aspects of the present disclosure are not limited thereto. The scan clock line SCL may be a gate clock line, but aspects of the present disclosure are not limited thereto.

The second scan clock line PSCL may be disposed outside the scan clock line SCL. For example, the second scan clock line PSCL may be disposed along the first direction outside the scan clock line SCL. The second scan clock line PSCL may transmit a second scan clock that is opposite in phase or different from the scan clock SCLK. For example, the second scan clock supplied to the second scan clock line PSCL may be out of phase or opposite to the scan clock SCLK supplied to the scan clock line SCL.

Additionally, a second emission clock line PECL may be disposed along the first direction outside the first emission clock line ECL. The second emission clock line PECL may transmit a second emission clock whose phase is opposite to that of the emission clock ECLK. For example, the second scan clock line PSCL may be disposed between the scan clock line SCL and the emission clock line ECL. The second emission clock line PECL may be disposed outside the emission clock line ECL. The second emission clock line PECL may be a pseudo emission clock line, but aspects of the present disclosure are not limited thereto.

In addition, the second scan clock line PSCL and the second emission clock line PECL may extend along the second direction in the second area Area2 where the gate driving circuit 120 is not disposed, and form a closed loop. The second area Area2 may be an upper area of the display panel 110, and the second direction may be horizontal direction.

Therefore, electromagnetic noise in the scan clock SCLK may be reduced by supplying a second scan clock whose phase is opposite to or different from the scan clock SCLK along the second scan clock line PSCL in a period when the scan clock SCLK is supplied along the scan clock line SCL. In addition, electromagnetic noise in the emission clock ECLK may be reduced by supplying a second emission clock whose phase is opposite to or different from the emission clock ECLK along the second emission clock line PECL in a period when the emission clock ECLK is supplied along the emission clock line ECL.

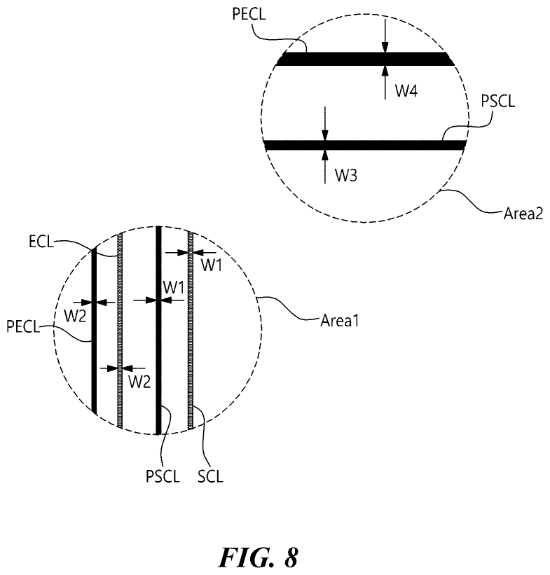

FIG. 8 illustrates a structure of a clock line according to aspects of the present disclosure.

Referring to FIGS. 7 and 8 together, the second scan clock line PSCL and the second emission clock line PECL in the display apparatus 100 according to aspects of the present disclosure may be disposed along the first area Area1 where the gate driving circuit 120 is disposed and the second area Area2 where the gate driving circuit 120 is not disposed. The second scan clock line PSCL and the second emission clock line PECL may be formed as a closed loop.

As the radiation amount of the second gate clock whose phase is opposite to or different from the gate clock is similar to the radiation amount of the gate clock, the effect of reducing electromagnetic noise may increase. Accordingly, the sum of width of the second gate clock lines may be formed to be similar to the sum of width of the gate clock lines.

Since the gate driving circuit 120 and various signal lines are disposed in the first area Area1, the second scan clock line PSCL and the second emission clock line PECL may be difficult to form thickly for a narrow bezel. On the other hand, since the gate driving circuit 120 or signal lines configured to drive the gate driving circuit 120 are not disposed in the second area Area2, the second scan clock line PSCL and the second emission clock line PECL may be formed thickly.

According to aspects of the present disclosure, the second scan clock line PSCL disposed in the first direction in the first area Area1 may be formed to be equal to the width WI of the scan clock line SCL. Additionally, the second emission clock line PECL disposed in the first direction in the first area Area1 may be formed to be equal to the width W2 of the emission clock line ECL. When the width W1 of the scan clock line SCL is the same as the width W2 of the emission clock line ECL, the width of the second scan clock line PSCL may be the same as the width of the second emission clock line PECL disposed in the first area Area1.

For another example, the width of the second scan clock line PSCL may be different from the width of the scan clock line SCL in the second area Area2. The second scan clock line PSCL and the second emission clock line PECL disposed in the second area Area2 may be formed with a different width from the scan clock line SCL and the emission clock line ECL. For example, the width of the second scan clock line PSCL may be thicker than the width of the scan clock line SCL in the second area Area2.

Since the gate driving circuit 120 or signal lines configured to drive the gate driving circuit 120 are not formed in the second area Area2, electromagnetic noise caused by the scan clock line SCL and the emission clock line ECL may be effectively reduced by forming the second scan clock line PSCL and the second emission clock line PECL with thick width.

As a clock line is disposed at the outside of the display panel, the shielding effect caused by other metal lines arranged vertically or horizontally is reduced, so the radiation amount of electromagnetic noise may increase. Therefore, to reduce the radiation amount of electromagnetic noise, the width of the outer second clock line among the second clock lines PSCL, PECL disposed in the second area Area2 may be thicker than the width of the inner second clock line.

For example, the width W3 of the second scan clock line PSCL disposed along the second direction in the second area Area2 may be formed to be 2 to 3 times thicker than the width W1 of the scan clock line SCL disposed in the first area Area1. In addition, the width W4 of the second emission clock line PECL disposed along the second direction in the second area Area2 may be formed to be 4 to 5 times thicker than the width W2 of the emission clock line ECL disposed in the first area Area1.

Since the second emission clock line PECL is located outside the second scan clock line PSCL in the second area Area2, the width W4 of the second emission clock line PECL may be formed thicker than the width W3 of the second scan clock line PSCL.

As another example, when the second scan clock line PSCL is disposed outside the second emission clock line PECL in the second area Area2, the width W3 of the second scan clock line PSCL may be formed thicker than the width W4 of the second emission clock line PECL.

Therefore, an effect of reducing the electromagnetic noise may be further improved and a narrow bezel may be implemented by forming thickly the width of the second scan clock line PSCL and the second emission clock line PECL disposed in the second area Area2 where the gate driving circuit 120 or a signal line configured to drive the gate driving circuit 120 is not formed.

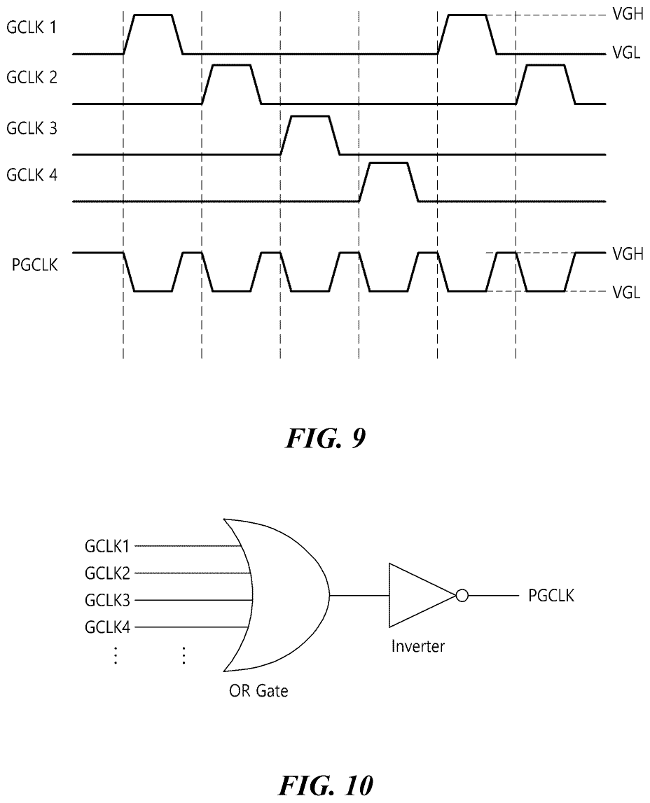

FIG. 9 illustrates waveforms of a gate clock and a second gate clock according to aspects of the present disclosure.

FIG. 9 illustrates a case in which four gate clock lines and one second gate clock line are disposed in the non-display area NDA in FIG. 7, and aspects of the present disclosure are not limited to this. When the gate clock line is the scan clock line SCL, the second gate clock line may be the second scan clock line PSCL. When the gate clock line is the emission clock line ECL, the second gate clock line may be the second emission clock line PECL.

Referring to FIGS. 7 and 9 together, the display apparatus 100 according to aspects of the present disclosure may include a second gate clock line disposed along the outer or the perimeter of the gate clock line disposed in the non-display area NDA.

When gate clocks GCLK1-GCLK4 are supplied through the gate clock lines during the display driving period, electromagnetic noise caused by the gate clock GCLK1-GCLK4 may be reduced by supplying the second gate clock PGCLK whose phase is opposite to that of the gate clocks GCLK1-GCLK4 to the second gate clock line.

For example, the four gate clocks GCLK1-GCLK4 supplied through the four gate clock lines may form pulses at different times. Therefore, the second gate clock PGCLK whose phase is opposite to the four gate clocks GCLK1-GCLK4 may be supplied through the second gate clock line.

Here, it illustrates the case where one second gate clock PGCLK corresponds to four gate clocks GCLK1-GCLK4 as an example, and the number of second gate clock lines may be formed in various ways.

FIG. 10 illustrates a circuit configured to generate a second gate clock according to aspects of the present disclosure.

Here, when the gate clocks GCLK1, GCLK2, GCLK3, GCLK4, . . . are scan clocks, the second gate clock PGCLK may be the second scan clock, and the gate clocks GCLK1, GCLK2, GCLK3, GCLK4), . . . are the emission clocks, the second gate clock may be the second emission clock.

Referring to FIG. 10, the circuit configured to generate the second gate clock PGCLK in the display apparatus 100 according to aspects of the present disclosure may include an OR logic gate OR Gate connected to an inverter Inverter in series.

The OR logic gate OR Gate may receive a plurality of gate clocks GCLK1, GCLK2, GCLK3, GCLK4, . . . with different input timings and transmit them sequentially. The inverter Inverter may generate the second gate clock PGCLK by inverting each of the plurality of gate clocks GCLK1, GCLK2, GCLK3, GCLK4, . . .

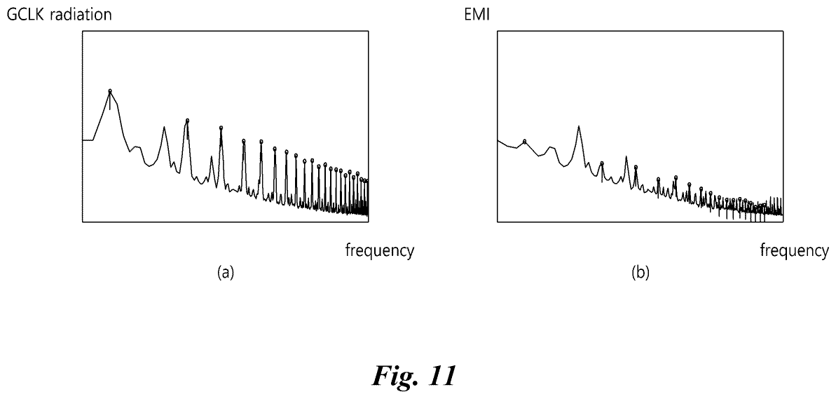

FIGS. 11A and 11B illustrate measuring noise according to aspects of the present disclosure.

The display apparatus 100 according to aspects of the present disclosure may include the second scan clock line PSCL and the second emission clock line PECL formed in a closed loop structure along the first area Area1 in which the gate driving circuit 120 is disposed and a second area Area2 in which the gate driving circuit 120 is not disposed.

The display apparatus 100 of aspect of the present disclosure may improve the reducing effect of electromagnetic noise by forming the widths of the second scan clock line PSCL and the second emission clock line PECL in the second area Area2, where the gate driving circuit 120 is not disposed, thicker than the width in the first area Area1, where the gate driving circuit 120 is disposed.

FIG. 11A is a graph illustrating the radiation amount of the gate clock GCLK according to frequency in decibel dB. FIG. 11B illustrates the electromagnetic noise detected when supplying the second gate clock through the second gate clock line disposed in the first area Area1 and the second area Area2 in decibel dB.

When the second clock line is arranged in this structure and the second gate clock is supplied, a significant portion of the radiation amount caused by the gate clock GCLK supplied to the gate driving circuit 120 may be reduced, thereby reducing electromagnetic noise.

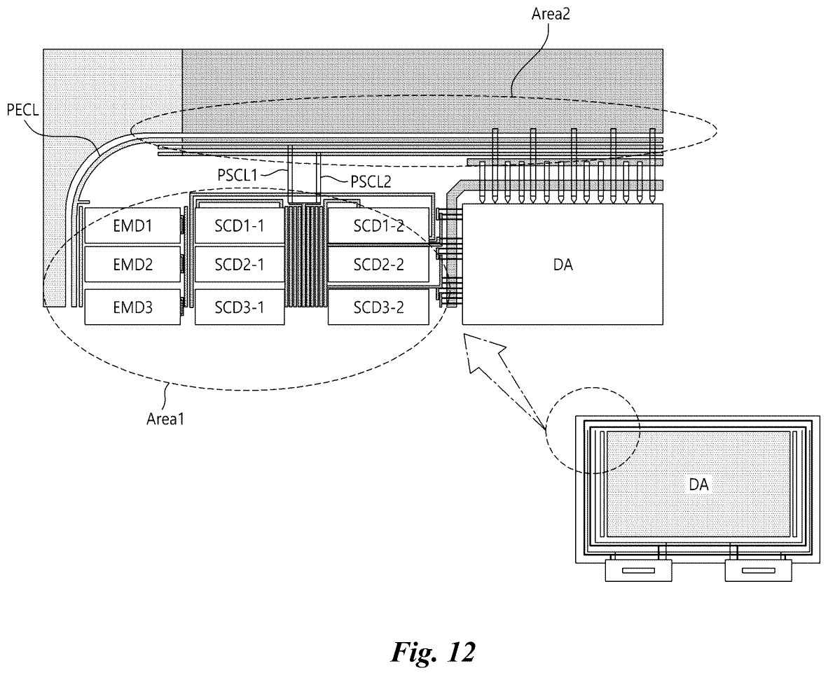

FIG. 12 illustrates the arrangement of clock lines according to aspects of the present disclosure.

FIG. 12 illustrates an example in which a subpixel SP is driven by a plurality of scan signals. In this case, each stage may be composed of a plurality of scan driving circuits.

Referring to FIG. 12, for example, in the case of the subpixel structure of FIG. 3, the gate signal supplied to each line may include one emission signal and two scan signals. In this case, the gate driving integrated circuit of the first line may include a first emission driving circuit EMD1 generating a first emission signal, a 1-1 scan driving circuit SCD1-1 generating a 1-1 scan signal and a 1-2 scan driving circuit SCD1-2 generating a 1-2 scan signal.

In addition, the gate driving integrated circuit of the second line may include a second emission driving circuit EMD2 generating a second emission signal, a 2-1 scan driving circuit SCD2-1 generating a 2-1 scan signal, and a 2-2 scan driving circuit SCD2-2 generating a 2-2 scan signal.

In addition, the gate driving integrated circuit of the third line may include a third emission driving circuit EMD3 generating a third emission signal, a 3-1 scan driving circuit SCD3-1 generating a 3-1 scan signal, and a 3-2 scan driving circuit SCD3-2 generating a 3-2 scan signal.

In this case, the second emission clock line PECL may be disposed outside the emission driving circuits EMD1, EMD2, EMD3 along the first area Area1 and may extend to the second area Area2.

The second scan clock line may include a 2-1 scan clock line PSCL1 disposed at the side of the scan driving circuits SCD1-1, SCD2-1, SCD3-1 in the first row and a 2-2 scan clock line PSCL2 disposed at the side of the scan driving circuits SCD1-2, SCD2-2, SCD3-2 in the second row.

The second scan clock lines PSCL1, PSCL2 may be disposed between the scan driving circuits SCD1-1, SCD2-1, SCD3-1 in the first row and the scan driving circuits SCD1-2, SCD2-2, SCD3-2 in the second row.

The second scan clock lines PSCL1, PSCL2 disposed in the first area Area1 may be formed with the same width as the scan clock lines. Additionally, the second emission clock line PECL disposed in the first area Area1 may be formed with the same width as the emission clock line.

For another example, the second scan clock lines PSCL1, PSCL2 and the second emission clock line PECL disposed in the second area Area2 may be formed with widths thicker than the scan clock line and the emission clock line.

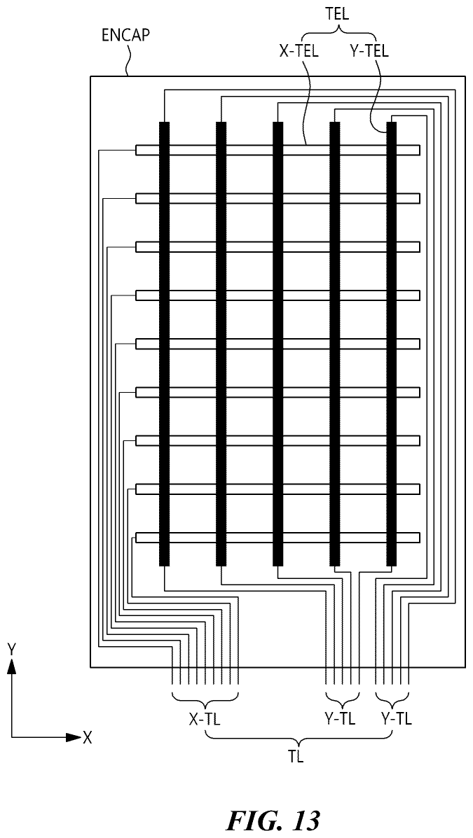

FIG. 13 illustrates a touch electrode structure in a display apparatus according to aspects of the present disclosure.

Referring to FIG. 13, the display apparatus 100 according to aspects of the present disclosure may have a touch electrode structure for mutual capacitance-based touch sensing. For example, the touch electrode structure may include a plurality of X-touch electrode lines X-TEL and a plurality of Y-touch electrode lines Y-TEL. The plurality of X-touch electrode lines X-TEL and the plurality of Y-touch electrode lines Y-TEL are located on the encapsulation layer ENCAP.

The plurality of X-touch electrode lines X-TEL each may be disposed in a first direction, and the plurality of Y-touch electrode lines Y-TEL each may be disposed in a second direction different from the first direction.

In aspects of the present disclosure, the first direction and the second direction may be relatively different directions. As an example, the first direction may be the x-axis direction, and the second direction may be the y-axis direction. In contrast, the first direction may be the y-axis direction, and the second direction may be the x-axis direction. The first direction and the second direction may be, or may not be, perpendicular to each other. In the present disclosure, row and column are relative terms, and from a point of view, the terms “row” and “column” may be interchangeably used.

Each of the X-touch electrode lines X-TEL may be constituted of a plurality of X-touch electrodes electrically connected with each other. Each of the Y-touch electrode lines Y-TEL may be constituted of a plurality of Y-touch electrodes electrically connected with each other.

The plurality of X-touch electrodes and the plurality of Y-touch electrodes are included in the plurality of touch electrodes TE and whose roles (functions) are distinguished.

For example, the plurality of X-touch electrodes respectively constituting the plurality of X-touch electrode lines X-TEL may be driving touch electrodes, and the plurality of Y-touch electrodes respectively constituting the plurality of Y-touch electrode lines Y-TEL may be sensing touch electrodes. In this case, the plurality of X-touch electrode lines X-TEL respectively correspond to driving touch electrode lines, and the plurality of Y-touch electrode lines Y-TEL respectively correspond to sensing touch electrode lines.

In another example, the plurality of X-touch electrodes respectively constituting the plurality of X-touch electrode lines X-TEL may be sensing touch electrodes, and the plurality of Y-touch electrodes respectively constituting the plurality of Y-touch electrode lines Y-TEL may be driving touch electrodes. In this case, the plurality of X-touch electrode lines X-TEL respectively correspond to sensing touch electrode lines, and the plurality of Y-touch electrode lines Y-TEL respectively correspond to driving touch electrode lines.

A touch sensor metal for touch sensing may include a plurality of touch lines TL as well as the plurality of X-touch electrode lines X-TEL and the plurality of Y-touch electrode lines Y-TEL.

The plurality of touch lines TL may include one or more X-touch lines X-TL respectively connected to the plurality of X-touch electrode lines X-TEL and one or more Y-touch lines Y-TL respectively connected to the plurality of Y-touch electrode lines Y-TEL.

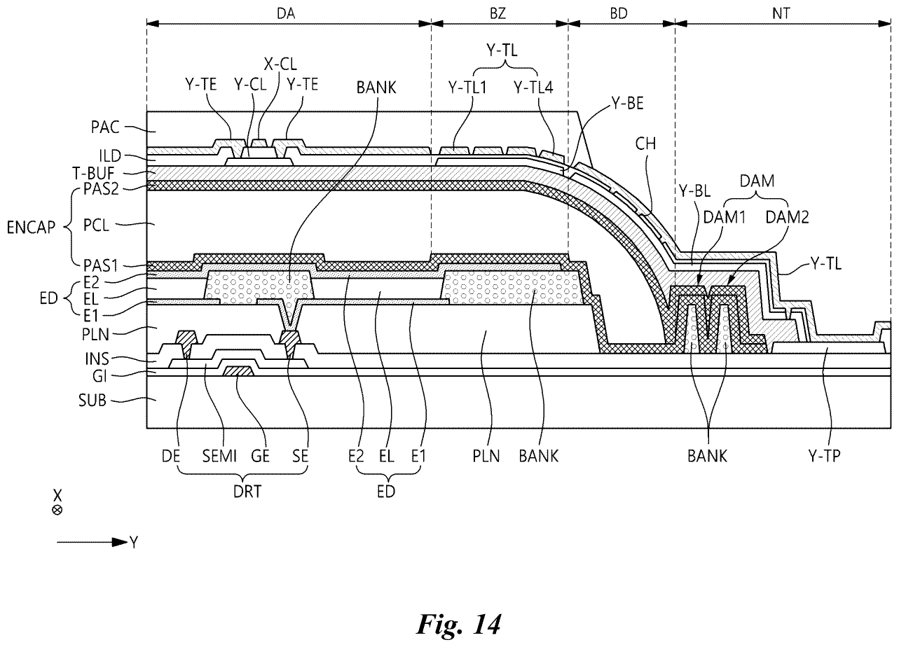

FIG. 14 is a cross-sectional view exemplarily illustrating a display apparatus according to aspects of the present disclosure.

In the display apparatus 100 according to aspects of the present disclosure, a driving transistor DRT may be disposed on the substrate SUB in the subpixel SP located in the display area DA. In FIG. 14, only the driving transistor DRT is shown, but a switching transistor and a storage capacitor included in the subpixel may also be included.

The driving transistor DRT may include a gate electrode GE, a source electrode SE, a drain electrode DE, and a semiconductor layer SEMI.

The gate electrode GE and the semiconductor layer SEMI may overlap each other, with the gate insulation film GI interposed therebetween. The source electrode SE may be formed on an insulation layer INS to contact one side of the semiconductor layer SEMI, and the drain electrode DE may be formed on the insulation layer INS to contact the other side of the semiconductor layer SEMI. For example, the semiconductor layer may include an oxide semiconductor layer or a low-temperature polysilicon semiconductor layer, but aspects of the present disclosure are not limited thereto.

The light emitting element ED may include a first electrode E1, which corresponds to the anode electrode (or cathode electrode), a emission layer EL formed on the first electrode E1, and a second electrode E2 formed on the emission layer EL and corresponding to the cathode electrode (or anode electrode).

The first electrode E1 may be electrically connected with the source electrode SE of the driving transistor DRT, exposed through a contact hole which passes through a planarization film PLN.

The emission layer EL may be disposed on the first electrode E1 in an emission area defined by a bank BANK. The emission layer EL may be formed in the order of hole-related layer, emission layer, and electron-related layer, or its reverse order, on the first electrode E1. The second electrode E2 may be formed to face the first electrode E1, with the emission layer EL disposed therebetween. For example, the hole-related layer may be a hole transport layer, a hole injection layer, an electron blocking layer, or a P-type charge generation layer, but aspects of the present disclosure are not limited thereto. For example, the electron-related layer may be an electron transport layer, an electron injection layer, a hole blocking layer, or an N-type charge generation layer, but aspects of the present disclosure are not limited thereto.

The encapsulation layer ENCAP blocks or at least reduces penetration of external moisture or oxygen into the light emitting element ED which is vulnerable to external moisture or oxygen. The encapsulation layer ENCAP may be formed of one layer or may include a stacked structure of a plurality of layers PAS1, PCL, and PAS2.

For example, where the encapsulation layer ENCAP is formed of a stacked structure of a plurality of layers PAS1, PCL, and PAS2, the encapsulation layer ENCAP may include one or more inorganic encapsulation layers PAS1 and PAS2 and one or more organic encapsulation layer PCL. For example, in the encapsulation layer ENCAP, the first inorganic encapsulation layer PAS1, the organic encapsulation layer PCL, and the second inorganic encapsulation layer PAS2 may be stacked in the order thereof, but aspects of the present disclosure are not limited thereto.

The encapsulation layer ENCAP may further include at least one organic encapsulation layer or at least one inorganic encapsulation layer, but aspects of the present disclosure are not limited thereto.

The first inorganic encapsulation layer PAS1 may be formed on the substrate SUB where the second electrode E2 corresponding to the cathode electrode is formed, to be disposed most adjacent to the light emitting element ED. The first inorganic encapsulation layer PAS1 is formed of an inorganic insulation material capable of low-temperature deposition, such as for example, silicon nitride (SiNx), silicon oxide (SiOx), silicon oxynitride (SiON), or aluminum oxide (Al₂O₃), but aspects of the present disclosure are not limited thereto. Since the first inorganic encapsulation layer PAS1 is deposed at low-temperature atmosphere, the first inorganic encapsulation layer PAS1 may prevent damage to the emission layer EL including the organic material vulnerable to high-temperature atmosphere during deposition.

The organic encapsulation layer PCL may be formed in a smaller area than the first inorganic encapsulation layer PAS1 in which case the organic encapsulation layer PCL may be formed to expose both ends of the first inorganic encapsulation layer PAS1. The organic encapsulation layer PCL serves to mitigate stress between the layers due to a bending of the display apparatus 100, while reinforcing the planarization performance. The organic encapsulation layer PCL may be formed of, e.g., an acrylic resin, epoxy resin, polyimide, polyethylene, silicon oxycarbide (SiOC), or other organic insulation materials, but aspects of the present disclosure are not limited thereto.

Where the organic encapsulation layer PCL is formed in an inkjet method, one or more dams DAM may be formed in the boundary area between the non-display area and the display area DA or the dam area which corresponds to a portion of the non-display area.

For example, the dam area may be disposed between the display area DA and the pad area where the plurality of touch pads are formed in the non-display area and, in the dam area, a primary dam DAM1 adjacent to the display area DA, and a secondary dam DAM2 adjacent to the pad area may exist.

The one or more dams DAM disposed in the dam area may prevent or at least reduce the liquid-state organic encapsulation layer PCL from collapsing toward the non-display area and resultantly penetrating into the pad area when the liquid-phase organic encapsulation layer PCL is disposed on the display area DA.

The primary dam DAM1 or the secondary dam DAM2 may be formed in a single-layer structure or multi-layer structure. For example, the primary dam DAM1 or the secondary dam DAM2 may simultaneously be formed of the same material as at least one of the bank BANK and a spacer. In this case, a dam structure may be formed without an additional masking process or cost. For example, spacers may be disposed on the bank BANK. For example, the BANK may be formed of a material including black pigment, or an organic material such as benzocyclobutene resin, polyimide resin, acrylic resin, or photosensitive polymer, but aspects of the present disclosure are not limited thereto. If the BANK is composed of a material including black pigment or black dye, it may be a black bank. When the BANK is formed of a material including black pigment or black dye, light from the outside may be blocked and the luminance of the display apparatus may be further improved.

The primary dam DAM1 or the secondary dam DAM2 may be structured so that the first inorganic encapsulation layer PAS1 and the second inorganic encapsulation layer PAS2 are stacked on the bank BANK. In this case, the organic encapsulation layer PCL including an organic material may be disposed on an inner surface of the primary dam DAM1 or be disposed on the upper portion of at least a portion of the primary dam DAM1 and the secondary dam DAM2.

The second inorganic encapsulation layer PAS2 may be formed over the substrate SUB, where the organic encapsulation layer PCL is formed, to cover the upper surface and side surfaces of each of the organic encapsulation layer PCL and the first inorganic encapsulation layer PAS1. The second inorganic encapsulation layer PAS2 may reduce or block penetration of external moisture or oxygen into the first inorganic encapsulation layer PAS1 and the organic encapsulation layer PCL. The second inorganic encapsulation layer PAS2 may be formed of an inorganic insulation material, such as, e.g., silicon nitride (SiNx), silicon oxide (SiOx), silicon oxynitride (SiON), or aluminum oxide (Al₂O₃), but aspects of the present disclosure are not limited thereto.

A touch part may be formed on the encapsulation layer ENCAP. Each of a plurality of X-touch electrode lines in the touch part may include a plurality of X-touch electrodes X-TE arranged in the same row (or column), and one or more X-touch electrode connection lines X-CL. The X-touch electrode connection line X-CL connecting two adjacent X-touch electrodes X-TE may be formed of metal integrated with the two adjacent X-touch electrodes X-TE or may be a metal connecting the two adjacent X-touch electrodes X-TE through a contact hole, but aspects of the present disclosure are not limited thereto.

A touch buffer layer T-BUF may be disposed on the encapsulation layer ENCAP. The touch buffer layer T-BUF may be positioned between the touch sensor metal including the touch electrodes X-TE and Y-TE and the touch electrode connection lines X-CL and Y-CL, and the second electrode E2 of the light emitting element ED.

The touch buffer layer T-BUF may be formed to maintain a predetermined distance (e.g., 1 μm) between the touch sensor metal and the second electrode E2 of the light emitting element ED, but aspects of the present disclosure are not limited thereto. Thus, it is possible to reduce or prevent the parasitic capacitance formed between the touch sensor metal and the second electrode E2 of the light emitting element ED, and thus, reduce or prevent deterioration of touch sensitivity due to parasitic capacitance.

In another example, without the touch buffer layer T-BUF, the touch sensor metal including the touch electrodes X-TE and Y-TE and the touch electrode connection lines X-CL and Y-CL may be disposed on the encapsulation layer ENCAP.

The touch buffer layer T-BUF may block or at least reduce penetration, into the organic material-containing emission layer EL, of external moisture or the chemical (e.g., developer or etchant) used while manufacturing the touch sensor metal disposed on the touch buffer layer T-BUF. Thus, the touch buffer layer T-BUF may prevent damage to the emission layer EL vulnerable to chemicals or moisture. Therefore, the touch buffer layer T-BUF may be formed to cover the touch sensor metal to prevent the touch sensor metal from being corroded by external moisture, etc.

The touch buffer layer T-BUF may be formed of an organic insulation material with a low permittivity and formed at a low temperature which is not more than a predetermined temperature (e.g., 100° C.) to prevent or at least reduce damage to the emission layer EL containing the organic material vulnerable to high temperature, but aspects of the present disclosure are not limited thereto. For example, the touch buffer layer T-BUF may be formed of an acrylic-based material, epoxy-based material, or siloxane-based material, but aspects of the present disclosure are not limited thereto. The touch buffer layer T-BUF with planarizability, formed of an organic insulation material, may prevent fracture of the touch sensor metal formed on the touch buffer film T-BUF and damage to the internal layers PAS1, PCL, and PAS2 constituting the encapsulation layer ENCAP due to a bending of the display apparatus. For another example, the touch buffer layer T-BUF may not be on the encapsulation layer ENCAP. For example, the touch buffer layer T-BUF may be omitted.

In a mutual-capacitance-based touch sensor structure, the X-touch electrode line X-TEL and the Y-touch electrode line Y-TEL may be formed on the touch buffer layer T-BUF, and the X-touch electrode line X-TEL and the Y-touch electrode line Y-TEL may be disposed to cross each other. The Y-touch electrode line Y-TEL may include a plurality of Y-touch electrode connection lines Y-CL that electrically connect the plurality of Y-touch electrodes Y-TE.

In this case, the plurality of Y-touch electrodes Y-TE and the plurality of Y-touch electrode connection lines Y-CL may be disposed on different layers, with the inter-layer dielectric ILD interposed therebetween.

The plurality of Y-touch electrodes Y-TE may be spaced apart at a predetermined interval along the y axis direction. The plurality of Y-touch electrodes Y-TE may be electrically connected with another Y-touch electrode Y-TE adjacent thereto in the y axis direction via the Y-touch electrode connection line Y-CL.

The Y-touch electrode connection line Y-CL may be formed on the touch buffer layer T-BUF. The Y-touch electrode connection line Y-CL may be exposed via a touch contact hole passing through the inter-layer dielectric ILD and be electrically connected with two Y-touch electrodes Y-TE adjacent in the y axis direction.

The Y-touch electrode connection line Y-CL may be disposed to overlap the bank BANK. Thus, it is possible to prevent or at least reduce a reduction in the aperture ratio of the display apparatus due to the Y-touch electrode connection line Y-CL.

The X-touch electrode line X-TEL may include a plurality of X-touch electrode connection lines X-CL that electrically connect the plurality of X-touch electrodes X-TE. The plurality of X-touch electrodes X-TE and the plurality of X-touch electrode connection lines X-CL may be positioned on different layers, with the inter-layer dielectric ILD disposed therebetween.

The plurality of X-touch electrodes X-TE may be spaced apart at a predetermined interval along the x axis direction, on the inter-layer dielectric ILD. The plurality of X-touch electrodes X-TE may be electrically connected with another X-touch electrode X-TE adjacent thereto in the x axis direction via the X-touch electrode connection line X-CL.

The X-touch electrode connection line X-CL may be disposed on the same plane as the X-touch electrode X-TE and be electrically connected with two X-touch electrodes X-TE adjacent thereto in the x axis direction without a separate contact hole or be integrated with the two X-touch electrodes X-TE adjacent thereto each other in the x axis direction.

The X-touch electrode connection line X-CL may be disposed to overlap the bank BANK. Thus, it is possible to prevent a reduction in the aperture ratio of the display apparatus due to the X-touch electrode connection line X-CL.

The Y-touch electrode line Y-TEL may be electrically connected with the touch circuit 150 via the Y-touch line Y-TL and the Y-touch pad Y-TP. Likewise, the X-touch electrode line X-TEL may be electrically connected with the touch circuit 150 via the X-touch line X-TL and the X-touch pad.

A pad cover electrode may be further provided to cover the X-touch pad and the Y-touch pad Y-TP.

The X-touch pad may be formed separately from the X-touch line X-TL or may extend from the X-touch line X-TL. The Y-touch pad Y-TP may be formed separately from the Y-touch line Y-TL or may extend from the Y-touch line Y-TL.

Where the X-touch pad extends from the X-touch line X-TL, and the Y-touch pad Y-TP extends from the Y-touch line Y-TL, the X-touch pad, the X-touch line X-TL, the Y-touch pad Y-TP, and the Y-touch line Y-TL may be formed of the same first conductive material. The first conductive material may be formed in a single-layer or multi-layer structure by a metal with good corrosion or acid resistance or electric conductivity, such as Aluminum (Al), titanium (Ti), copper (Cu), or molybdenum (Mo), but aspects of the present disclosure are not limited thereto.

For example, the X-touch pad, X-touch line X-TL, Y-touch pad Y-TP, and Y-touch line Y-TL formed of the first conductive material may be formed in a three-layer stacked structure, such as Ti/Al/Ti or Mo/Al/Mo, but aspects of the present disclosure are not limited thereto.

The pad cover electrode capable of covering the X-touch pad and Y-touch pad Y-TP may be formed of a second conductive material which is the same material as the X-touch electrode and Y-touch electrode X-TE and Y-TE. The second conductive material may be formed of a transparent conductive material, such as ITO or IZO, which has high corrosion or acid resistance. The pad cover electrode may be formed to be exposed by the touch buffer layer T-BUF, and thus, may be bonded with the touch driving circuit 150 or a circuit film where the touch driving circuit 150 is mounted.

The touch buffer layer T-BUF may be formed to cover the touch sensor metal, preventing or at least reducing corrosion to the touch sensor metal by external moisture. As an example, the touch buffer layer T-BUF may be formed of an organic insulation material or a film form of a circular polarizer or epoxy or acrylic material. The touch buffer layer T-BUF on the encapsulation layer ENCAP may be omitted . . .

The Y-touch line Y-TL may be electrically connected with the Y-touch electrode via a touch line contact hole or be integrated with the Y-touch electrode Y-TE.

The Y-touch line Y-TL may extend up to the non-display area and be electrically connected with the Y-touch pad Y-TP via the top and side of the encapsulation layer ENCAP and the top and side of the dam DAM. Thus, the Y-touch line Y-TL may be electrically connected with the touch circuit 150 via the Y-touch pad Y-TP.

The Y-touch line Y-TL may transfer the touch sensing signal from the Y-touch electrode Y-TE to the touch circuit 150 or may receive the touch driving signal from the touch circuit 150 and transfer the touch driving signal to the Y-touch electrode Y-TE.

In the notch area NT and bending area BD, the Y-touch bridge line Y-BL connected through the contact hole CH may be disposed under the Y-touch line Y-TL. Since the Y-touch line Y-TL and the Y-touch bridge line Y-BL are electrically connected through at least one contact hole CH formed at constant intervals, the same touch driving signal or touch sensing signal may be transferred.

Therefore, when the Y-touch line Y-TL and the Y-touch bridge line Y-BL are electrically connected, the electrical resistance may be reduced during the transfer of the touch driving signal or the touch sensing signal. Further, when connecting the Y-touch line Y-TL and the Y-touch bridge line Y-BL through a plurality of contact holes CH, the touch signal (touch driving signal or touch sensing signal) may get around through the contact hole CH although a disconnection occurs in the Y-touch line Y-TL or Y-touch bridge line Y-BL in some portion, so that the performance of touch sensing may be maintained.

The area other than the contact hole CH may be insulated by the inter-layer dielectric ILD disposed between the Y-touch line Y-TL and the Y-touch bridge line Y-BL.

A plurality of Y-touch lines Y-TL1, Y-TL2, Y-TL3, and Y-TL4 may be disposed in the bezel area BZ, and the Y-touch bridge electrode Y-BE having an integrated structure may be disposed under the plurality of Y-touch lines Y-TL1, Y-TL2, Y-TL3, and Y-TL4.

The Y-touch bridge electrode Y-BE may have an integrated structure and be formed to have the same width or a larger width than the Y-touch lines Y-TL1, Y-TL2, Y-TL3, and Y-TL4 to be able to cover the area occupied by the Y-touch lines Y-TL1, Y-TL2, Y-TL3, and Y-TL4 positioned above the Y-touch lines Y-TL1, Y-TL2, Y-TL3, and Y-TLA.

The Y-touch bridge electrode Y-BE may be connected to a ground voltage GND to discharge the noise charge introduced into the display panel 110 and may be separated from the Y-touch bridge line Y-BL or the second node electrode NE2 positioned in the bending area BD.

Thus, the noise charge introduced to the display panel 110 may easily be discharged to the ground voltage GND by the Y-touch bridge electrode Y-BE formed in an integrated structure to be able to cover the area occupied by the Y-touch lines Y-TL1, Y-TL2, Y-TL3, and Y-TLA, so that the touch sensing performance of the display apparatus 100 may be reduced, and defects during display driving may be reduced.

The X-touch line X-TL may be electrically connected with the X-touch electrode X-TE via the touch line contact hole or may be integrated with the X-touch electrode X-TE.

The X-touch line X-TL may extend up to the non-display area and be electrically connected with the X-touch pad (not shown) via the top and side of the encapsulation layer ENCAP and the top and side of the dam DAM. Thus, the X-touch line X-TL may be electrically connected with the touch circuit 150 via the X-touch pad X-TP.

The X-touch line X-TL may receive the touch driving signal form the touch circuit 150 and transfer the touch driving signal to the X-touch electrode X-TE and may transfer the touch sensing signal from the X-touch electrode X-TE to the touch circuit 150.

Various changes may be formed to the arrangement of the X-touch line X-TL and the Y-touch line Y-TL depending on the design of the display panel 110.

A touch protection film PAC may be disposed on the X-touch electrode X-TE and the Y-touch electrode Y-TE. The touch protection film PAC may extend up to before or after the dam DAM, and thus, may be disposed even on the X-touch line X-TL and the Y-touch line Y-TL.

The cross-sectional views in the FIG. 14 illustrate a conceptual structure of a touch display apparatus 100. Depending on the direction or position in which it is viewed, the position, thickness, or width of each pattern (e.g., various layers or electrodes) may be varied, and the connection structure of various patterns may be varied, and an additional layer other than the layers shown may be present as well, or some of the layers may be omitted or combined. For example, the width of the bank BANK may be narrower than that shown in the drawings, and the height of the dam DAM may be higher or lower than shown.

The display apparatus 100 may be used in mobile apparatus such as smartphones or tablet PCs, and may also be used in large-screen display apparatuses such as automobile displays and exhibition displays.

The display apparatus 100 may determine the presence or location of a touch by detecting a touch sensing signal transmitted from the touch electrode TE using a single sensing or differential sensing method.

The display panel 110 according to aspects the present disclosure may include first subpixels and second subpixels having different emission angles together. The viewing angle of the image may be controlled by selectively adjusting the driving operation of the first subpixels or the second subpixels.

For above purpose, a plurality of unit subpixels may be disposed on the display panel 110.

The unit subpixel may be a subpixel that emits light of a specified color. The unit subpixel may include a first subpixel with a first emission angle and a second subpixel with a second emission angle. The unit subpixel may be a unit subpixel that emits red color, a unit subpixel that emits green color, or a unit subpixel that emits blue color.

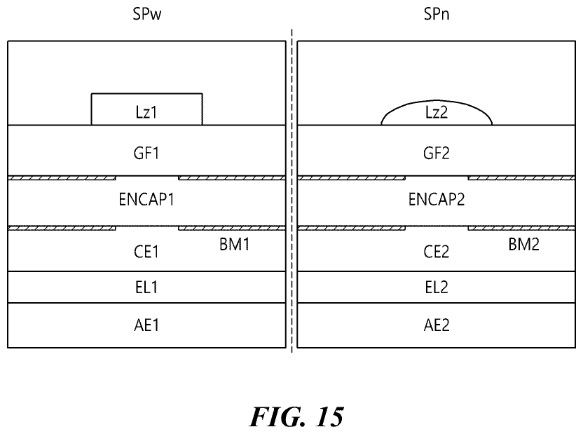

FIG. 15 is a cross-sectional diagram of a unit subpixel according to aspects of the present disclosure.

Referring to FIG. 15, the unit subpixel disposed on the display panel 110 in the display apparatus 100 according to aspects of the present disclosure may include a first subpixel SPw with a first emission angle and a second subpixel SPn with a second emission angle.

The first emission angle emitted through the first subpixel SPw may be greater than the second emission angle emitted through the second subpixel SPn.

The first subpixel SPw may include a first anode electrode AE1, a first emission layer EL1, and a first cathode electrode CE1. The first anode electrode AE1, the first emission layer ELI, and the first cathode electrode CE1 may constitute a first light-emitting element.

A first black matrix BM1, a first insulating layer ENCAP1, a first gap filler GF1, and a first lens Lz1 with a first emission angle may be disposed on the first cathode electrode CE1. An auxiliary gap filler may be further disposed on the first lens Lz1.

A portion of the area of the first black matrix BMI overlapping with the first anode electrode AE1 may be open.

The second subpixel SPn may include a second anode electrode AE2, a second emission layer EL2, and a second cathode electrode CE2. The second anode electrode AE2, the second emission layer EL2, and the second cathode electrode CE2 may constitute a second light-emitting element.

A second black matrix BM2, a second insulating layer ENCAP2, a second gap filler GF2, and a second lens Lz2 with a second emission angle may be disposed on the second cathode electrode CE2. An auxiliary gap filler may be further disposed on the second lens Lz2.

A portion of the area of the second black matrix BM2 overlapping with the second anode electrode AE2 may be open.

The first black matrix BMI and the second black matrix BM2 may prevent light from being incident to the active layer of a driving transistor constituting a subpixel to prevent leakage current from being generated.

The first anode electrode AE1 of the first subpixel SPw and the second anode electrode AE2 of the second subpixel SPn may be formed in the same process, on the same layer, with the same material, and with the same thickness, but aspects of the present disclosure are not limited thereto. The first anode electrode AE1 and the second anode electrode AE2 may be formed through a mask process using photoresist.

The first emission layer ELI of the first subpixel SPw and the second emission layer EL2 of the second subpixel SPn may be formed with the same material, same color, and same thickness on the same layer through a same process, but aspects of the present disclosure are not limited thereto.

Each of the first emission layer ELI and the second emission layer EL2 may include a hole injecting layer (HIL), a hole transporting layer (HTL), an electron blocking layer (EBL), an emitting material layer (EML), an electron transporting layer (ETL), a hole blocking layer HBL, and an electron injecting layer (EIL), but aspects of the present disclosure are not limited thereto.

The first cathode electrode CE1 of the first subpixel SPw and the second cathode electrode CE2 of the second subpixel SPn may be formed with the same material, same color, and same thickness on the same layer through a same process, but aspects of the present disclosure are not limited thereto.

The first cathode electrode CE1 and the second cathode electrode CE2 may be formed of an opaque metal material, such as at least one of aluminum (Al), tungsten (W), copper (Cu), molybdenum (Mo), chromium (Cr), tantalum (Ta), titanium (Ti), and alloys of combinations thereof, but aspects of the present disclosure are not limited thereto.

The first gap filler GF1 of the first subpixel SPw and the second gap filler GF2 of the second subpixel SPn may be formed with the same material, same color, and same thickness on the same layer through a same process, but aspects of the present disclosure are not limited thereto.

A space (or a distance) between the first emission layer ELI and the first lens Lz1 may be adjusted based on the thickness (height) of the first gap filler GF1. Further, a space (or a distance) between the second emission layer EL2 and the second lens Lz2 may be adjusted based on the thickness (height) of the second gap filler GF2.

The first gap filler GF1 or the second gap filler GF2 may be formed of one of acrylic, epoxy, and silicon or combinations thereof. Further, the first gap filler GF1 or the second gap filler GF2 may be formed of an organic material, but aspects of the present disclosure are not limited thereto.

A particle size in the first gap filler GF1 or the second gap filler GF2 may be equal to a wavelength of light, or may be larger or smaller than the wavelength of light by a certain range. The first gap filler GF1 or the second gap filler GF2 may have forward diffusion property based on one of a particle density, a particle size, and a particle shape.

The first gap filler GF1 or the second gap filler GF2 may have a smaller refractive index than that of the first insulating layer ENCAP1. For example, the first gap filler GF1 and the second gap filler GF2 may have a smaller refractive index than that of the first insulating layer ENCAP1 by one of the particle density, size, and shape.

A material of the first insulating layer ENCAP1 or the second insulating layer ENCAP2 may be one of TiO₂, Al₂O₃, and SiO₂, but aspects of the present disclosure are not limited thereto.

When the material of the first insulating layer ENCAP1 or the second insulating layer ENCAP2 is TiO₂, the first insulating layer ENCAP1 or the second insulating layer ENCAP2 may have a refractive index in a range of 2.6 to 2.9. When the material of the first insulating layer ENCAP1 or the second insulating layer ENCAP2 is Al₂O₃, the first insulating layer ENCAP1 or the second insulating layer ENCAP2 may have a refractive index in a range of 1.75 to 1.76. When the material of the first insulating layer ENCAP1 or the second insulating layer ENCAP2 is SiO₂, the first insulating layer ENCAP1 or the second insulating layer ENCAP2 may have a refractive index in a range of 1.40 to 1.55.

The first lens Lz1 disposed in the first subpixel SPw with a wide emission angle may be a cylinder-type lens, and the second lens Lz2 disposed in the second subpixel SPn with a narrow emission angle may be a circular type lens, but is not limited thereto.

The first lens Lz1 of the first subpixel SPw and the second lens Lz2 of the second subpixel SPn may be formed with the same material, same color, and same thickness on the same layer through a same process. However, the first lens Lz1 and the second lens Lz2 may be formed to have different shapes and different sizes.

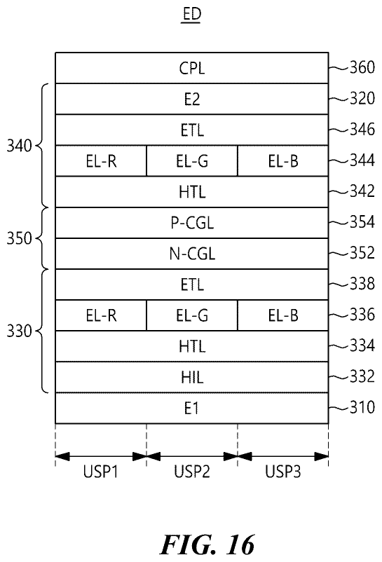

FIG. 16 illustrates a light emitting element according to aspects of the present disclosure.

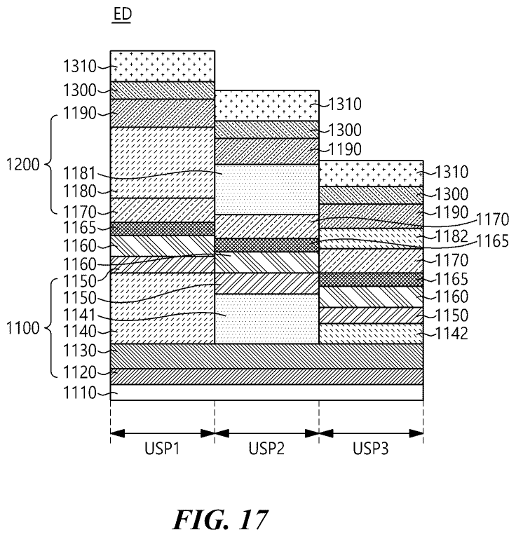

Referring to FIG. 16, the light emitting element ED of the subpixel in the display apparatus 100 according to aspects of the present disclosure may include a first electrode 310 and a second electrode 320. Also, the light emitting element ED may include a first emission part 330, a second emission part 340 and a charge generation layer 350 between the first electrode 310 and the second electrode 320. The description included in FIG. 16 may be included in the description included in FIG. 17.

The first electrode 310 as an anode electrode may include a conductive material with a high work function, but is not limited thereto. The second electrode 320 as a cathode electrode may include a conductive material with a low work function, but is not limited thereto.

The first emission part 330 may include a hole injection layer 332, a first hole transport layer 334, a first emission layer 336, and a first electron transport layer 338, but is not limited thereto.

The hole injection layer 332 may be disposed between the first electrode 310 and the first emission layer 336. For example, the hole injection layer 332 may include at least one of MTDATA (4,4′,4″-tris(N-3-methylphenyl-N-phenylamino)triphenylamine), CuPc (copper phthalocyanine), and TCTA (tris(4-carbazoyl-9-ylphenyl)amine), NPB(N,N′-di(naphthalen-1-yl)-N,N′-diphenyl-benzidine), NPD (N,N-dinaphthyl-N,N′-diphenyl benzidine), HATCN (1,4,5,8,9,11-hexaazatriphenylene-hexanitrile), TDAPB (1,3,5-tris(4-diphenylaminophenyl)benzene), PEDOT/PSS(Poly(3,4-ethylene dioxythiophene)/Polystyrene sulfonate), F4TCNQ (2,3,5,6-tetrafluoro-7,7,8,8-tetracyanl-quinidimethane), N-(biphenyl-4-yl)-9,9-dimethyl-N-4-(9-phenyl-9H-carbazol-3-yl)phenyl)-9H-fluoren-2-amine, but is not limited thereto.

The first hole transport layer 334 may be disposed between the hole injection layer 332 and the first emission layer 336. The first emission layer 336 may be disposed between the first hole transport layer 334 and the first electron transport layer 338. Additionally, the first electron transport layer 338 may be disposed between the first emission layer 336 and the charge generation layer 350.

The second emission part 340 may include a second hole transport layer 342, a second emission layer 344, and a second electron transport layer 346, but is not limited thereto.

The second emission layer 344 may be disposed between the second hole transport layer 342 and the second electron transport layer 346. The second electron transport layer 346 may be disposed between the second emission layer 344 and the second electrode 320.

The electron injection layer may be further disposed between the second electron transport layer 346 and the second electrode 320. The electron injection layer may include an alkali halide compound, e.g., LiF, CsF, NaF or BaF2, or an organo-metallic compound, e.g., lithium quinolate (Liq), lithium benzoate or sodium stearate, but is not limited thereto.

Each of the first emission layer 336 and the second emission layer 344 may be formed by doping a host with a dopant, and may emit the same color or different colors.

For example, the first emission layer 336 and the second emission layer 344 may include a red emission layer EL-R, a green emission layer EL-G, and a blue emission layer EL-B, respectively. The red emission layer EL-R may form a first subpixel area USP1 that emits red color. The green emission layer EL-G may form a second subpixel area USP2 that emits green color. The blue emission layer EL-B may form a third subpixel area USP3 that emits blue color.

The first hole transport layer 334 and the second hole transport layer 342 may be formed of the same material or may be formed of different materials.

The first electron transport layer 338 and the second electron transport layer 346 may be formed of oxadiazole, triazole, phenanthroline, benzoxazole, benzthiazole or benzimidazole (e.g., 2-[4-(9,10-Di-2-naphthalenyl-2-anthracenyl)phenyl]-1-phenyl-1H-benzimidazole), but aspects of the present disclosure are not limited thereto.

Each of the first electron transport layer 338 and the second electron transport layer 346 may include a dopant such as an alkali metal or an alkaline earth metal, but aspects of the present disclosure are not limited thereto. The first electron transport layer 338 and the second electron transport layer 346 may be formed of the same material or may be formed of different materials.

A charge generation layer (CGL) 350 may be disposed between the first emission part 330 and the second emission part 340. The charge generation layer 350 may be disposed between the emission parts to supply positive and negative charges to each emission part, respectively.

The charge generation layer 350 may include an N-type charge generation layer (N-CGL) 352 adjacent to the first emission part 330 and a P-type charge generation layer (P-CGL) 354 adjacent to the second emission part 340. The N-type charge generation layer 352 may supply electrons to the first emission part 330, and the P-type charge generation layer 354 may supply holes to the second emission part 340.

The N-type charge generation layer 352 may be an organic layer doped with an alkali metal such as Li, Na, K, Cs, and/or an alkaline earth metal such as Mg, Sr, Ba, and Ra, but are not limited thereto.

The second hole injection layer may be further disposed between the P-type charge generation layer 354 and the second hole transport layer 342 or between the N-type charge generation layer 352 and the P-type charge generation layer 354. When forming the second hole injection layer, holes generated in the P-type charge generation layer 354 may be efficiently injected and transferred to the second emission part 340.

The first hole injection layer 332 and the second hole injection layer may be formed of the same material or may be formed of different materials.

A capping layer 360 may be formed on the second electrode 320 to increase the light extraction effect of the light emitting element ED. The capping layer 360 may be formed of any one of the materials constituting the first and second hole transport layers 334, 342, or the materials constituting the first and second electron transport layers 338, 346, but aspects of the present disclosure are not limited thereto. As another example, the capping layer 360 may be formed of any one of the host materials of the first emission part 336 and the second emission part 344, but aspects of the present disclosure are not limited thereto. As another example, the capping layer 360 may be omitted.

A light emitting element ED with a tandem structure may lower the driving voltage and emit white color. Therefore, the display apparatus 100 may be driven at a low voltage, improve the life time of the light emitting element ED, and improve the emission efficiency.

When the display apparatus 100 according to aspects of the present disclosure may be formed to connect adjacent subpixels without a step in the charge generation layer 350, a horizontal current flows from the highly conductive charge generation layer 350 to adjacent subpixels. Thus, it may cause light leakage, where unwanted subpixels emit light together.

In another example, when the charge generation layer 350 is formed with a step, horizontal current may be reduced due to the high conductivity of the charge generation layer 350. Thus, the light leakage causing unwanted adjacent subpixels to be emitted together may be reduced.

FIG. 17 illustrates another example of a light-emitting element according to aspects of the present disclosure.

Referring to FIG. 17, the light emitting element ED of the display apparatus 100 according to aspects of the present disclosure may include emission parts 1100, 1200 between the first electrode 1110 and the second electrode 1300. The description included in FIG. 17 may be included in the description included in FIG. 16

The first electrode 1110 may include an indium-tin-oxide (ITO), and a silver alloy (Ag alloy), but is not limited thereto. For example, ITO may be formed to a thickness of 70 Å, a silver alloy (Ag alloy) may be formed on top (or an upper portion) of the ITO to a thickness of 1000 Å, and then ITO may be formed on top (or an upper portion) of the silver alloy to a thickness of 70 Å, but aspects of the present disclosure are not limited thereto.

The first emission part 1100 may be disposed on the first electrode 1110. The first emission part 1100 may include a hole injection layer 1120, a first hole transport layer 1130, an emission layer, and a first electron transport layer 1150, but aspects of the present disclosure are not limited thereto.

The hole injection layer 1120 may be formed on the first electrode 1110. The hole injection layer 1120 may be formed of HATCN (1,4,5,8,9,11-hexaazatriphenylene-hexanitrile), etc., but aspects of the present disclosure are not limited thereto. For example, the hole injection layer 1120 may be formed to a thickness of 70 Å, but aspects of the present disclosure are not limited thereto. The first hole transport layer 1130 may be formed on the hole injection layer 1120. The first hole transport layer 1130 may be formed of NPD (N,N-dinaphthyl-N,N′-diphenylbenzidine), etc., but aspects of the present disclosure are not limited thereto. For example, the first hole transport layer 1130 may be formed to a thickness of 500 Å, but aspects of the present disclosure are not limited thereto.

The 1-1 emission layer 1140 may be disposed in the red subpixel area USP1 on the first hole transport layer 1130. The 1-1 emission layer 1140 may include at least one host and at least one dopant. For example, the host material may be composed of a beryllium compound (Be complex) derivative, etc., but aspects of the present disclosure are not limited thereto. For example, after forming the host material to a thickness of 650 Å, the 1-1 emission layer 1140 may be formed by doping with a dopant at a level of 5%, but the aspects of the present disclosure are not limited thereto.

The 1-2 emission layer 1141 may be disposed in the green subpixel area USP2 on the first hole transport layer 1130. The 1-2 emission layer 1141 may include at least one host and at least one dopant. For example, the host material may be composed of CBP (carbazole biphenyl), etc., but aspects of the present disclosure are not limited thereto. For example, after forming the host material to a thickness of 400 Å, the 1-2 emission layer 1141 may be formed by doping with a dopant at a level of 5%, but the aspects of the present disclosure are not limited thereto.

The 1-3 emission layer 1142 may be disposed in the blue subpixel area USP3 on the first hole transport layer 1130. The 1-3 emission layer 1142 may include at least one host and at least one dopant. For example, the host material may be composed of an anthracene derivative, etc., but aspects of the present disclosure are not limited thereto. For example, after forming the host material to a thickness of 200 Å, the 1-3 emission layer 1142 may be formed by doping with a dopant at a level of 5%, but aspects of the present disclosure are not limited thereto.

For example, the thickness of the 1-1 emission layer 1140 may be thicker than the thickness of the 1-2 emission layer 1141. For example, the thickness of the 1-1 emission layer 1140 may be thicker than the thickness of the 1-3 emission layer 1142. For example, the thickness of the 1-2 emission layer 1141 may be thicker than the thickness of the 1-3 emission layer 1142. For example, the thickness of the 1-1 emission layer 1140 may be thicker than the thickness of each of the 1-2 emission layer 1141 and the 1-3 emission layer 1142.

The first electron transport layer 1150 may be disposed on the 1-1 emission layer 1140, the 1-2 emission layer 1141, and the 1-3 emission layer 1142. For example, the first electron transport layer 1150 may include an anthracene derivative and lithium quinolate (Liq), but aspects of the present disclosure are not limited thereto. For example, an anthracene derivative and Liq (lithium quinolate) may be mixed in a ratio of 1:1, but aspects of the present disclosure are not limited thereto. The first electron transport layer 1150 may be formed to a thickness of 70 Å, but aspects of the present disclosure are not limited thereto.

For another example, a hole blocking layer may be further formed under the first electron transport layer 1150. The hole blocking layer may be formed on the 1-1 emission layer 1140, the 1-2 emission layer 1141, and the 1-3 emission layer 1142.

An N-type charge generation layer (N-CGL) 1160 may be formed on the first electron transport layer 1150, and a P-type charge generation layer (P-CGL) 1165 may be formed on the N-type charge generation layer 1160. The N-type charge generation layer 1160 may be formed of Alq3, etc., but aspects of the present disclosure are not limited thereto. For example, the N-type charge generation layer 1160 may be formed to a thickness of 100 Å and then doped with lithium (Li), but aspects of the present disclosure are not limited thereto. The P-type charge generation layer 1165 may be formed on the N-type charge generation layer 1160 by HATCN, etc., but aspects of the present disclosure are not limited thereto. The P-type charge generation layer 1165 may be formed to a thickness of 100 Å to form a charge generation layer with a thickness of 200 Å, but aspects of the present disclosure are not limited thereto.

The second emission part 1200 may be disposed on the charge generation layer. The second emission part 1200 may include a second hole transport layer 1170, an emission layer, and a second electron transport layer 1190, but aspects of the present disclosure are not limited thereto. For example, the charge generation layer may be disposed between the first emission part 1100 and the second emission part 1200.

A second hole transport layer 1170 may be formed on the charge generation layer. The second hole transport layer 1170 may be formed of NPD or the like, but aspects of the present disclosure are not limited thereto. The second hole transport layer 1170 may be formed to a thickness of 400 Å, but aspects of the present disclosure are not limited thereto. For example, the thickness of the second hole transport layer 1170 may be greater than or equal to the thickness of the first hole transport layer 1130, but aspects of the present disclosure are not limited thereto.

The 2-1 emission layer 1180 may be formed in the red subpixel area USP1 on the second hole transport layer 1170. The 2-1 emission layer 1180 may include at least one host and at least one dopant. The 2-1 emission layer 1180 may be composed of a host material, such as a beryllium compound (Be complex) derivative, but aspects of the present disclosure are not limited thereto. The host material may be formed to a thickness of 650 Å and then doped with a dopant at a level of 5% to form the 2-1 emission layer 1180, but aspects of the present disclosure are not limited thereto.

For another example, a hole transport layer may be further disposed under the 2-1 emission layer 1180. The hole transport layer may further improve the emission efficiency of the 2-1 t emission layer 1180. The hole transport layer may be disposed between the second hole transport layer 1170 and the 2-1 emission layer 1180. For example, the hole transport layer may be formed of the same material as the second hole transport layer 1170, but aspects of the present disclosure are not limited thereto. For example, the thickness of the hole transport layer may be thicker than the thickness of the second hole transport layer 1170, but aspects of the present disclosure are not limited thereto.

The 2-2 emission layer 1181 may be formed in the green subpixel area USP2 on the second hole transport layer 1170. The 2-2 emission layer 1181 may include at least one host and at least one dopant. The 2-2 emission layer 1181 may be composed of a host material such as CBP, but aspects of the present disclosure are not limited thereto. The host material may be formed to a thickness of 400 Å and then doped with a dopant at a level of 5% to form the 2-2 emission layer 1181, but aspects of the present disclosure are not limited thereto.

The 2-3 emission layer 1182 may be formed in the blue subpixel area USP3 on the second hole transport layer 1170. The 2-3 emission layer 1182 may include at least one host and at least one dopant. The 2-3 emission layer 1182 may include an anthracene derivative as a host material, but aspects of the present disclosure are not limited thereto. The host material may be formed to a thickness of 200 Å and then doped with a dopant at a level of 5% to form the 2-3 emission layer 1182, but aspects of the present disclosure are not limited thereto.

For example, the thickness of the 2-1 emission layer 1180 may be thicker than the thickness of the 2-2 emission layer 1181. For example, the thickness of the 2-1 emission layer 1180 may be thicker than the thickness of the 2-3 emission layer 1182. For example, the thickness of the 2-2 emission layer 1181 may be thicker than the thickness of the 2-3 emission layer 1182. For example, the thickness of the 2-1 emission layer 1180 may be thicker than each of the 2-2 emission layer 1181 and the 2-3 emission layer 1182.

For example, the thickness of the 1-1 emission layer 1140 may be the same as or different from the thickness of the 2-1 emission layer 1180. For example, the thickness of the 1-2 emission layer 1141 may be the same as or different from the thickness of the 2-2 emission layer 1181. For example, the thickness of the 1-3 emission layer 1142 may be the same as or different from the thickness of the 2-3 emission layer 1182.

A second electron transport layer 1190 may be formed on the 2-1 emission layer 1180, the 2-2 emission layer 1181, and the 2-3 emission layer 1182. The second electron transport layer 1190 may be composed of an anthracene derivative, lithium quinolate (Liq), etc., but aspects of the present disclosure are not limited thereto. For example, an anthracene derivative and Liq (lithium quinolate) may be mixed at a ratio of 1:1 to form a thickness of 300 Å, but aspects of the present disclosure are not limited thereto. For example, the thickness of the second electron transport layer 1190 may be greater than or equal to the thickness of the first electron transport layer 1150, but aspects of the present disclosure are not limited thereto.

For example, the emission layer of the first emission part 1100 may emit the same color as the emission layer of the second emission part 1200. For example, the 1-1 emission layer 1140 of the first emission part 1100 may emit the same color as the 2-1 emission layer 1180 of the second emission part 1200. For example, the 1-2 emission layer 1141 of the first emission part 1100 may emit the same color as the 2-2 emission layer 1181 of the second emission part 1200. For example, the 1-3 emission layer 1142 of the first emission part 1100 may emit the same color as the 2-3 emission layer 1182 of the second emission part 1200.

For another example, a hole blocking layer may be further formed under the second electron transport layer 1190. The hole blocking layer may be formed on the 2-1 emission layer 1180, the 2-2 emission layer 1181, and the 2-3 emission layer 1182.

The second electrode 1300 may be formed on the second electron transport layer 1190. For example, the second electrode 1300 may be formed of magnesium (Mg), silver (Ag), etc., but aspects of the present disclosure are not limited thereto. For example, a magnesium-silver alloy (Mg:Ag) obtained by mixing magnesium (Mg) and silver (Ag) at a ratio of 9:1 may be formed to a thickness of 140 Å, but aspects of the present disclosure are not limited thereto. The second electrode 1300 may be a semi-transmissive electrode.

A capping layer 1310 may be formed on the second electrode 1300. The capping layer 1310 may be composed of one or more layers, but aspects of the present disclosure are not limited thereto. The capping layer 1310 may reduce damage to the second electrode 1300 of the light emitting element ED and the organic material layers below the second electrode 1300 from an external light source. The capping layer 1310 may be formed of an organic or inorganic film. The capping layer 1310 may be an inorganic layer formed of a material such as LiF, and may further include an organic layer, but aspects of the present disclosure are not limited thereto. For example, the capping layer 1310 may be composed of a stacked structure of an organic film and an inorganic film, and the thickness of the organic film may be different from the thickness of the inorganic film. For example, the thickness of the organic film may be greater than the thickness of the inorganic film. As another example, the capping layer 1310 may be composed of two or more layers by stacking materials with different refractive indices. Thus, the emission efficiency of the display apparatus 100 may be improved.

Considering the step between subpixels of the light emitting element ED based on the first electrode 1110, the gap between the 1-1 emission layer 1140 and the 1-2 emission layer 1141 may be formed at a level of 250 Å, the step between the 1-2 emission layer 1141 and the 1-3 emission layer 1142 may be formed at a level of 200 Å. Also, the step between the 1-3 emission layer 1142 and the 1-1 emission layer 1140 may be formed at a level of 250 Å.

In the light emitting element ED according to aspects of the present disclosure, since the step between the 1-1 emission layer 1140 and the 1-2 emission layer 1141, the step between the 1-2 emission layer 1141 and the 1-3 emission layer 1142, and the step between the 1-3 emission layer 1142 and the 1-1 emission layer 1140 is formed, the charge generation layers 1160 may have steps with each other in the red, green, and blue subpixel areas of the upper portion of the emission layer. For example, in the light emitting element ED according to aspects the present disclosure, since the step between the 1-1 emission layer 1140 and the 1-2 emission layer 1141, the step between the 1-2 emission layer 1141 and the 1-3 emission layer 1142 and the step between the 1-3 light emitting layer 1142 and the 1-1 light emitting layer 1140 are all formed at a level of 200 Å or more, the charge generation layers 1160 formed in the red, green, and blue subpixel areas on the emission layer also have a step of 200 Å or more.

Accordingly, the charge generation layer 1160 in the red subpixel area USPI, the charge generation layer 1160 in the green subpixel area USP2, and the charge generation layer 1160 in the blue subpixel area USP3 may not be substantially connected to each other. The meaning that the charge generation layers 1160 are not substantially connected between two subpixel areas may mean that the charge generation layers 1160 formed in each subpixel area are separated by the step or horizontal current hardly flows even if the charge generation layers 1160 formed in each subpixel area are not separated by the gap. Accordingly, the charge generation layers 1160 may be substantially insulated with each other by the step.

The light emitting element ED constituting the display apparatus 100 according to aspects the present disclosure does not generate horizontal current due to the high conductivity of the charge generation layer 1160. Therefore, a light leakage phenomenon in which unwanted adjacent subpixels emit light together may be reduced.

A display apparatus and a display panel according to aspects of the present disclosure are briefly described below.

A display apparatus according to aspects of the present disclosure may comprise a display panel including a plurality of subpixels in a display area, a gate driving circuit disposed along a first direction in a first area of the display panel, a gate clock line disposed along the first direction in the first area, and a second gate clock line disposed along the first direction in the first area, and disposed along a second direction in a second area of the display panel.

According to aspects of the present disclosure, the second gate clock line may be disposed outside the gate clock line.

According to aspects of the present disclosure, the second gate clock line is configured to receive a second gate clock that has a phase different from a gate clock supplied to the gate clock line.

According to aspects of the present disclosure, a width of the second gate clock line may be the same as a width of the gate clock line in the first area.

According to aspects of the present disclosure, a width of the second gate clock line may be different from a width of the gate clock line in the second area.

According to aspects of the present disclosure, a width of the second gate clock line may be thicker than a width of the gate clock line in the second area.

According to aspects of the present disclosure, the gate clock line may include an emission clock line and a scan clock line. The second gate clock line may include a second emission clock line disposed at a side of the emission clock line, and a second scan clock line disposed at a side of the scan clock line.

According to aspects of the present disclosure, the second emission clock line may be disposed outside the second scan clock line.

According to aspects of the present disclosure, a width of the second emission clock line may be the same as a width of the emission clock line in the first area.

According to aspects of the present disclosure, a width of the second emission clock line in the second area may be different from a width of the emission clock line.

According to aspects of the present disclosure, a width of the second scan clock line may be a same as a width of the scan clock line in the first area.

According to aspects of the present disclosure, a width of the second scan clock line in the second area may be different from a width of the scan clock line.

According to aspects of the present disclosure, the gate driving circuit may include a scan driving circuit. The scan driving circuit may include a first scan driving circuit configured to supply a first scan signal to a first line subpixel, and a second scan driving circuit configured to supply a second scan signal to the first line subpixel. The second scan clock line may include a 2-1 scan clock line and a 2-2 scan clock line disposed between the first scan driving circuit and the second scan driving circuit.

According to aspects of the present disclosure, the second emission clock line and the second scan clock line may each have a closed loop shape.

According to aspects of the present disclosure, the display apparatus may further comprise a transistor in the display area, a light emitting element over the transistor, and an encapsulation layer over the light emitting element.

According to aspects of the present disclosure, a semiconductor layer of the transistor may include an oxide semiconductor layer or a low-temperature polysilicon semiconductor layer.

According to aspects of the present disclosure, the display apparatus may further comprise a touch part on the encapsulation layer.

According to aspects of the present disclosure, the light emitting element may include a first emission part and a second emission part disposed between a first electrode and a second electrode. The first emission part may include an emission layer configured to emit a same color as the second emission part.

A display panel according to aspects of the present disclosure may comprise a display area including a plurality of subpixels, a gate driving circuit disposed along a first direction in a first area of a non-display area outside of the display area, a first gate clock line disposed along the first direction in the first area, and a second gate clock line disposed along the first direction in the first area, and disposed along a second direction in a second area of the none-display area.

According to aspects of the present disclosure, a width of the second gate clock line may be ae same as a width of the first gate clock line in the first area.

According to aspects of the present disclosure, a width of the second gate clock line in the second area may be thicker than a width of the first gate clock line.

According to aspects of the present disclosure, the first gate clock line may include an emission clock line and a scan clock line. The second gate clock line may include a second emission clock line disposed at a side of the emission clock line, and a second scan clock line disposed at a side of the scan clock line.

According to aspects of the present disclosure, the second emission clock line may be disposed outside the second scan clock line.

According to aspects of the present disclosure, a width of the second emission clock line in the second area may be different from a width of the emission clock line.

According to aspects of the present disclosure, a width of the second scan clock line may be the same as a width of the scan clock line in the first area.

According to aspects of the present disclosure, a width of the second scan clock line in the second area may be different from a width of the scan clock line.

According to aspects of the present disclosure, the gate driving circuit may include a scan driving circuit. The scan driving circuit may include a first scan driving circuit configured to supply a first scan signal to a first line subpixel, and a second scan driving circuit configured to supply a second scan signal to the first line subpixel. The second scan clock line may include a 2-1 scan clock line and a 2-2 scan clock line disposed between the first scan driving circuit and the second scan driving circuit.

According to aspects of the present disclosure, the second gate clock line may be configured to receive a second gate clock that has a phase different from a first gate clock supplied to the first gate clock line.

It will be apparent to those skilled in the art that various modifications and variations may be made in the present disclosure without departing from the scope of the disclosures. Thus, it is intended that the present disclosure covers the modifications and variations of this disclosure provided they come within the scope of the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel including a plurality of subpixels in a display area;
a gate driving circuit disposed along a first direction in a first area of the display panel;
a gate clock line disposed along the first direction in the first area; and
a second gate clock line disposed along the first direction in the first area, and disposed along a second direction in a second area of the display panel.

2. The display apparatus of claim 1, wherein the second gate clock line is disposed outside the gate clock line.

3. The display apparatus of claim 1, wherein the second gate clock line is configured to receive a second gate clock that has a phase different from a gate clock supplied to the gate clock line.

4. The display apparatus of claim 1, wherein a width of the second gate clock line is a same as a width of the gate clock line in the first area.

5. The display apparatus of claim 1, wherein a width of the second gate clock line is different from a width of the gate clock line in the second area.

6. The display apparatus of claim 1, wherein a width of the second gate clock line in the second area is thicker than a width of the gate clock line.

7. The display apparatus of claim 1, wherein the gate clock line includes an emission clock line and a scan clock line, and
wherein the second gate clock line includes:
a second emission clock line disposed at a side of the emission clock line; and
a second scan clock line disposed at a side of the scan clock line.

8. The display apparatus of claim 7, wherein the second emission clock line is disposed outside the second scan clock line.

9. The display apparatus of claim 7, wherein a width of the second emission clock line is a same as a width of the emission clock line in the first area.

10. The display apparatus of claim 7, wherein a width of the second emission clock line in the second area is different from a width of the emission clock line.

11. The display apparatus of claim 7, wherein a width of the second scan clock line is a same as a width of the scan clock line in the first area.

12. The display apparatus of claim 7, wherein a width of the second scan clock line in the second area is different from a width of the scan clock line.

13. The display apparatus of claim 7, wherein the gate driving circuit includes a scan driving circuit,
wherein the scan driving circuit includes:
a first scan driving circuit configured to supply a first scan signal to a first line subpixel; and
a second scan driving circuit configured to supply a second scan signal to the first line subpixel, and
wherein the second scan clock line includes a 2-1 scan clock line and a 2-2 scan clock line disposed between the first scan driving circuit and the second scan driving circuit.

14. The display apparatus of claim 7, wherein the second emission clock line and the second scan clock line each have a closed loop shape.

15. The display apparatus of claim 1, further comprising:
a transistor in the display area;
a light emitting element over the transistor; and
an encapsulation layer over the light emitting element.

16. The display apparatus of claim 15, wherein a semiconductor layer of the transistor includes an oxide semiconductor layer or a low-temperature polysilicon semiconductor layer.

17. The display apparatus of claim 15 further comprising a touch part on the encapsulation layer.

18. The display apparatus of claim 15, wherein the light emitting element includes a first emission part and a second emission part disposed between a first electrode and a second electrode, and
wherein the first emission part includes an emission layer configured to emit a same color as the second emission part.

19. A display panel, comprising:
a display area including a plurality of subpixels;
a gate driving circuit disposed along a first direction in a first area of a non-display area outside of the display area;
a first gate clock line disposed along the first direction in the first area; and
a second gate clock line disposed along the first direction in the first area, and disposed along a second direction in a second area of the non-display area.

20. The display panel of claim 19, wherein a width of the second gate clock line is a same as a width of the first gate clock line in the first area.

21. The display panel of claim 19, wherein a width of the second gate clock line in the second area is thicker than a width of the first gate clock line.

22. The display panel of claim 19, wherein the first gate clock line includes an emission clock line and a scan clock line, and
wherein the second gate clock line includes:
a second emission clock line disposed at a side of the emission clock line; and
a second scan clock line disposed at a side of the scan clock line.

23. The display panel of claim 22, wherein the second emission clock line is disposed outside the second scan clock line.

24. The display panel of claim 22, wherein a width of the second emission clock line in the second area is different from a width of the emission clock line.

25. The display panel of claim 22, wherein a width of the second scan clock line is a same as a width of the scan clock line in the first area.

26. The display panel of claim 22, wherein a width of the second scan clock line in the second area is different from a width of the scan clock line.

27. The display panel of claim 19, wherein the gate driving circuit includes a scan driving circuit,
wherein the scan driving circuit includes:
a first scan driving circuit configured to supply a first scan signal to a first line subpixel; and
a second scan driving circuit configured to supply a second scan signal to the first line subpixel, and
wherein the second scan clock line includes a 2-1 scan clock line and a 2-2 scan clock line disposed between the first scan driving circuit and the second scan driving circuit.

28. The display panel of claim 19, wherein the second gate clock line is configured to receive a second gate clock that has a phase different from a first gate clock supplied to the first gate clock line.
